(19) United States
(12) Patent Application Publication
(10) Pub. No.: US 2007/0111111 A1
(43) Pub. Date: May 17, 2007

(54) Light measurement apparatus and light measurement method

(75) Inventor: Kazunori Tanimura, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: YOKOGAWA ELECTRIC CORPORATION

(21) Appl. No.: 11/598,745

(22) Filed: Nov. 14, 2006

(30) Foreign Application Priority Data
Nov. 15, 2005 (JP) 2005-330045
Jul. 13, 2006 (JP) 2006-193070

(51) Int. Cl. G03F 1/00

(52) U.S. Cl. 430/5

(57) ABSTRACT

Disclosed is a light measurement apparatus including: an optical branching device to branch light to be measured into a plurality of pieces; a time delay processing unit to give a predetermined time delay to one branched piece of the light; an optical phase diversity circuit to output an in-phase signal component and a quadrature-phase signal component of the light to be measured by interference of the light to be measured and a reference standard light whose relative time difference is a time given by the time delay, wherein the reference standard light is another branched piece of the light or the one branched piece of the light having been subjected the time delay; and a data processing circuit to calculate at least one of an amplitude variation and a phase variation of the light to be measured based on the in-phase signal component and the quadrature-phase signal component.

### BACKGROUND OF THE INVENTION

1. Field of the Invention

The present invention relates to a light measurement apparatus and a light measurement method which measure at least one of the amplitude and the phase of an optical signal.

2. Description of Related Art

In recent years, as a modulation method of a transmission signal used for optical communication, a phase modulation method which adds information to the phase of light has been proposed in addition to a conventional intensity modulation method. As a digital phase modulation method, for example, there are binary phase-shift keying (BPSK) in which phases 0 and π of the light correspond to binary digital values, differential phase-shift keying (DPSK) in which a digital value is discriminated based on a phase difference between bits adjoining each other, and the like. Moreover, multilevel modulation methods such as amplitude phase-shift keying (APSK) in which a digital value is added to both the amplitude and the phase, and the like have been also proposed. As the researches of such phase modulation methods have advanced, the demand for an apparatus and a method to measure the phase of light quantitatively has been being increased.

With reference to FIGS. 26-28, a description is given to a measurement technique which has been proposed in “Measurement of Eye Diagrams and Constellation Diagrams of Optical Sources Using Linear Optics and Waveguide Technology,” by C. Dorrer, Christopher Richard Doerr, I. Kang, Roland Ryf, J. Leuthold, P.J. Winzer, Journal of Lightwave Technology, Vol. 23, No. 1, January 2005, pp. 178-186 (hereinafter referred to as non-patent document 1). The light measurement system disclosed in the non-patent document 1 is composed of a sampling laser 301 which generates sampling light, an optical signal generation apparatus 302 which generates light to be measured, a trigger signal generator 303, an optical band-pass filter 304, a polarization controller 305 which adjusts the polarization of the light to be measured, an optical phase diversity circuit 306, differential optical receivers 307 and 308, and an AD converter 309, as shown in FIG. 26. The trigger signal generator 303 generates a trigger signal for synchronizing the sampling laser 301 and the AD converter 309 with each other.

The light measurement system shown in FIG. 26 is based on the principle of optical sampling to sample the amplitude and the phase of light to be measured sequentially to plot the sampled values using the optical phase diversity circuit 306 referring to the amplitude and the phase of the sampling light which is stably oscillated. FIG. 27 shows the configuration of the optical phase diversity circuit 306. The sampling light and the light to be measured which have been input into the optical phase diversity circuit 306 are branched by splitters S_{S} and S_{D}, respectively, and are multiplexed by couplers C_{A} and C_{B}. Each of the interference signals corresponding to the in-phase signal component and the quadrature-phase signal component of the electric field of the input light to be measured is obtained by differential optical receivers S_{A} and S_{B} by giving the phase difference of π2 to one of the sampling light branched by the splitter S_{S} with a phase adjuster 310 using the amplitude and the phase of the sampling light as references.

When the optical electric field of the light to be measured is denoted by e_{D}(t) and the optical electric field of the sampling light is denoted by e_{S}(t), the optical electric fields e_{D}(t) and e_{S}(t) are expressed by the following expressions (1) and (2), respectively.
e_{D}(t)=E_{D}(t)exp[−iω_{D}t+iφ(t)+iψ] (1)
e_{S}(t)=E_{S}(t)exp[−iω_{S}t] (2)

where ω_{D} denotes the optical carrier frequency of the light to be measured and ω_{S} denotes the optical carrier frequency of the sampling light. In the expression (1), E_{D}(t) denotes the envelope of the optical electric field of the light to be measured, φ (t) denotes a temporal phase change of a carrier wave, and ψ denotes an initial phase (the relative phase to the sampling light). If the light to be measured is a phase-modulated signal, the phase change φ (t) shows a different value to each bit, and the change of the phase change φ (t) is the object of measuring. In the expression (2), E_{S}(t) denotes the envelope of the optical electric field of the sampling light.

An N^{th} data obtained in the sampling regarding interference signals s_{A} and s_{B} obtained using the optical phase diversity circuit 306 at each period T are expressed by the following expressions (3) and (4).
s_{A}(NT)=2·\sqrt{P}·E_{D}(NT)·cos [−(ω_{D}−ω_{S})NT+φ(NT)+ψ] (3)
s_{B}(NT)=2·\sqrt{P}·E_{D}(NT)·sin [−(ω_{D}−ω_{S})NT+φ(NT)+ψ] (4)

where the sampling light is approximated to a delta function. Moreover, P denotes the intensity of the sampling light.

Consequently, the magnitudes of the interference signals become ones reflecting the amplitude E_{D}(t) and the phase φ (t) of the light to be measured at a sampling point. It is possible to measure the amplitude variation and the phase variation (the variation of the amplitude E_{D}(t) and the variation of the phase φ (t)) of the light to be measured by analyzing the obtained sampling data expressed by the expressions (3) and (4).

FIG. 28 shows an example of an amplitude phase distribution in which amplitude variations and phase variations are displayed on a complex plane. As shown in FIG. 28, the amplitude phase distribution can be obtained by plotting the magnitude s_{A}(NT) of the in-phase signal component as the x coordinate, and the magnitude of the quadrature-phase signal component s_{B}(NT) of each sampling point as the y coordinate.

Although the aforesaid conventional measurement technique uses the sampling technique, the technique basically conforms to optical heterodyne measurement. A measurement technique of the phase of light based on the optical heterodyne measurement is generally easily influenced by the wavelength fluctuations of local light (sampling light), and it is required for the technique to prepare a stable light source such as one provided with a feedback mechanism. Moreover, it is necessary for obtaining an interference signal with the optical phase diversity circuit that the wavelengths of the light to be measured and the local light are comparable with each other. Consequently, a measurable wavelength range is limited in the conventional measurement technique depending on the local light.

Moreover, although the intensity variation (amplitude variation) of an optical signal can be measured using a waveform measuring apparatus such as an optical oscilloscope, it is not easy to measure a phase variation. Although it is considered that the technique using the optical phase diversity circuit is effective as the technique of measuring the phase variation as mentioned above, the conventional technique needs to prepare the local light, and a measurement object and measurement accuracy strongly depend on the performance of the local light.

### SUMMARY OF THE INVENTION

It is an object of the present invention to enable to measure the amplitude variation and the phase variation of an optical signal without using any local light.

In order to attain the above object, according to a first aspect of the invention, a light measurement apparatus comprising: an optical branching device to branch light to be measured into a plurality of pieces; a time delay processing unit to give a predetermined time delay to one branched piece of the light to be measured; an optical phase diversity circuit to output an in-phase signal component and a quadrature-phase signal component of the light to be measured by interference of the light to be measured with a reference standard light whose relative time difference is a time given by the time delay, wherein the reference standard light is another branched piece of the light to be measured or the one branched piece of the light to be measured having been subjected to processing of the time delay processing unit; and a data processing circuit to calculate at least one of an amplitude variation and a phase variation of the light to be measured based on the in-phase signal component and the quadrature-phase signal component.

The light measurement apparatus may further comprise an optical time gate processing unit to extract at least one branched piece of the light to be measured in every predetermined bit time, the optical time gate processing unit being provided on a path from the optical branching device to the optical phase diversity circuit.

The light measurement apparatus may further comprise an optical time gate processing unit to switch an optical carrier frequency of at least one branched piece of the light to be measured in every predetermined bit time, the optical time gate processing unit being provided on a path from the optical branching device to the optical phase diversity circuit.

The light measurement apparatus may further comprise an optical time gate processing unit to extract the light to be measured in every predetermined bit time, and to output the extracted light to be measured to the optical branching device.

The light measurement apparatus may further comprises an electric time gate processing unit to extract the in-phase signal component and the quadrature-phase signal component in every predetermined bit time, and to output the extracted in-phase signal component and the extracted quadrature-phase signal component to the data processing circuit.

According to the present invention, it becomes possible to measure the amplitude variation and the phase variation of light to be measured without using any local light. In particular, using an optical time gate processing unit or an electric time gate processing unit makes it possible to measure the amplitude variation and the phase variation of the light to be measured with an AD converter and a data processing circuit the operating frequency bands of which are low.

The light measurement apparatus may further comprise an optical clock recovery circuit to generate a clock signal synchronizing with the light to be measured.

The setting of generating a clock signal that is synchronized with the light to be measured with an optical clock recovery circuit makes it possible to measure the amplitude variation and the phase variation of the light to be measured without using any clock signals that are input from the outside.

Preferably, the light to be measured is an optical signal on which a pseudo random code is superimposed, and the data processing circuit performs data processing using a frame signal synchronizing with a repetition frequency of the pseudo random code.

If an optical signal on which a pseudo random code is superimpose is used as the light to be measured, performing data processing using a frame signal that is synchronized with a repetition frequency of the pseudo random code makes it possible to measure the state of the amplitude change or the phase change of the light to be measured at each bit.

The light measurement apparatus may further comprises a multiplexer to multiplex the another branched piece of the light to be measured with the one branched piece of the light to be measured which has been subjected to the time delay, and to output the multiplexed light to the optical time gate processing unit, wherein the optical time gate processing unit extracts the light to be measured multiplexed by the multiplexer in every predetermined bit time.

Multiplexing the branched light to be measured and the time-delayed light to be measured to perform the processing by the optical time gate processing unit in a lump to the multiplexed light to be measured makes it possible to achieve the reduction of noises at the time of light receiving because only the signal necessary for obtaining data is input into the optical phase diversity circuit.

Preferably, the optical time gate processing unit extracts each branched piece of the light to be measured in every predetermined bit time, and the optical phase diversity circuit makes the branched pieces of the light to be measured processed by the optical time gate processing unit interfere with each other.

Performing the processing of extracting different bits to each piece of the branched light to be measured also makes it possible to achieve the reduction of the noises at the time of light receiving because only the signal necessary for obtaining data is input into the optical phase diversity circuit.

Preferably, the optical time gate processing unit switches the optical carrier frequency of each branched piece of the lights to be measured in every predetermined bit time, and the optical phase diversity circuit makes the branched pieces of the light to be measured processed by the optical time gate processing unit interfere with each other.

Performing the processing of switching an optical carrier frequency of each piece of the branched light to be measured every predetermined bit time makes it possible to obtain an interference signal of a predetermined bits even if the variation of the optical carrier frequency is small because the frequency difference between each signal that is made to interfere with each other in the optical phase diversity circuit can be set to be large.

The light measurement apparatus may further comprise a polarization split device to split the light to be measured into a plurality of polarization components perpendicular to one another, wherein processing of the optical branching device, the time delay processing unit and the optical phase diversity circuit is performed to each of the polarization components split by the polarization split device.

Using a polarization split device makes it possible to split the light to be measured into a plurality of polarization components perpendicular to each other to perform the amplitude measurement and the phase measurement of each of the polarization components independently.

The light measurement apparatus may further comprise a measurement unit to measure intensity of at least one of the light to be measured and the reference standard light.

Measuring the intensity of the light to be measured or the reference standard light independently (of amplitude phase measurements) to use the measured intensity in data processing makes it possible to improve measurement accuracy.

The light measurement apparatus may further comprise a display unit to display an amplitude phase distribution of the light to be measured based on a processing result of the data processing circuit.

Displaying the amplitude phase distribution of the light to be measured makes it possible to evaluate the quality of the light to be measured.

According to a second aspect of the invention, a light measurement method comprising the steps of: branching light to be measured into a plurality of pieces; giving a predetermined time delay to one branched piece of the light to be measured; outputting an in-phase signal component and a quadrature-phase signal component of the light to be measured according to interference of the light to be measured with a reference standard light whose relative time difference is a time given by the time delay, wherein the reference standard light is another branched piece of the light to be measured or the one branched piece of the light to be measured to which the time delay has been given; calculating at least one of an amplitude variation and a phase variation of the light to be measured based on the in-phase signal component and the quadrature-phase signal component.

### BRIEF DESCRIPTION OF THE DRAWINGS

The present invention will become more fully understood from the detailed description given hereinbelow and the appended drawings which given by way of illustration only, and thus are not intended as a definition of the limits of the present invention, and wherein;

FIG. 1 is a block diagram showing the internal configuration of the light measurement apparatus according to a first embodiment of the present invention;

FIG. 2 is a diagram showing an example of the internal configuration of a waveguide type optical phase diversity circuit;

FIG. 3 is a diagram showing a time chart expressing the operation of the light measurement apparatus of the first embodiment;

FIG. 4 is a diagram showing an example of the amplitude phase distribution of a DPSK signal;

FIG. 5 is a diagram showing an example of the internal configuration of an optical phase diversity circuit using a space system optical element;

FIG. 6 is a diagram showing an example of the internal configuration of another optical phase diversity circuit using another space system optical element;

FIG. 7 is a diagram showing an example of the internal configuration of a further optical phase diversity circuit using a further space system optical element;

FIG. 8 is a block diagram showing the internal configuration of the light measurement apparatus according to a first modified example of the first embodiment;

FIG. 9 is a block diagram showing the internal configuration of the light measurement apparatus according to a second modified example of the first embodiment;

FIG. 10 is a block diagram showing the internal configuration of the light measurement apparatus according to a third modified example of the first embodiment;

FIG. 11 is a block diagram showing the internal configuration of the light measurement apparatus according to a fourth modified example of the first embodiment;

FIG. 12 is a block diagram showing the internal configuration of the light measurement apparatus according to a fifth modified example of the first embodiment;

FIG. 13 is a block diagram showing the internal configuration of the light measurement apparatus according to a. sixth modified example of the first embodiment;

FIG. 14 is a block diagram showing the internal configuration of the light measurement apparatus according to a seventh modified example of the first embodiment;

FIG. 15 is a diagram showing a display example of an amplitude phase distribution in the case where a locus of amplitude and phase changes of light is dynamically displayed;

FIG. 16 is a block diagram showing the internal configuration of the light measurement apparatus according to an eighth modified example of the first embodiment;

FIG. 17 is a block diagram showing the internal configuration of the light measurement apparatus according to a second embodiment of the present invention;

FIG. 18 is a diagram showing the operation of an optical carrier frequency converter;

FIG. 19 is a diagram showing a time chart expressing the operation of the light measurement apparatus of the second embodiment;

FIG. 20 is a block diagram showing the internal configuration of the light measurement apparatus according to a modified example of the second embodiment;

FIG. 21 is a block diagram showing the internal configuration of the light measurement apparatus according to a third embodiment of the present invention;

FIG. 22 is a diagram showing a time chart expressing the operation of the light measurement apparatus of the third embodiment;

FIG. 23 is a diagram showing an example of an element that includes both the functions of a time delay processing unit and an optical phase diversity circuit;

FIG. 24 is a block diagram showing the internal configuration of the light measurement apparatus according to a fourth embodiment of the present invention;

FIG. 25 is a diagram showing a time chart expressing the operation of the light measurement apparatus of the fourth embodiment;

FIG. 26 is a diagram showing the configuration of a conventional light measurement system;

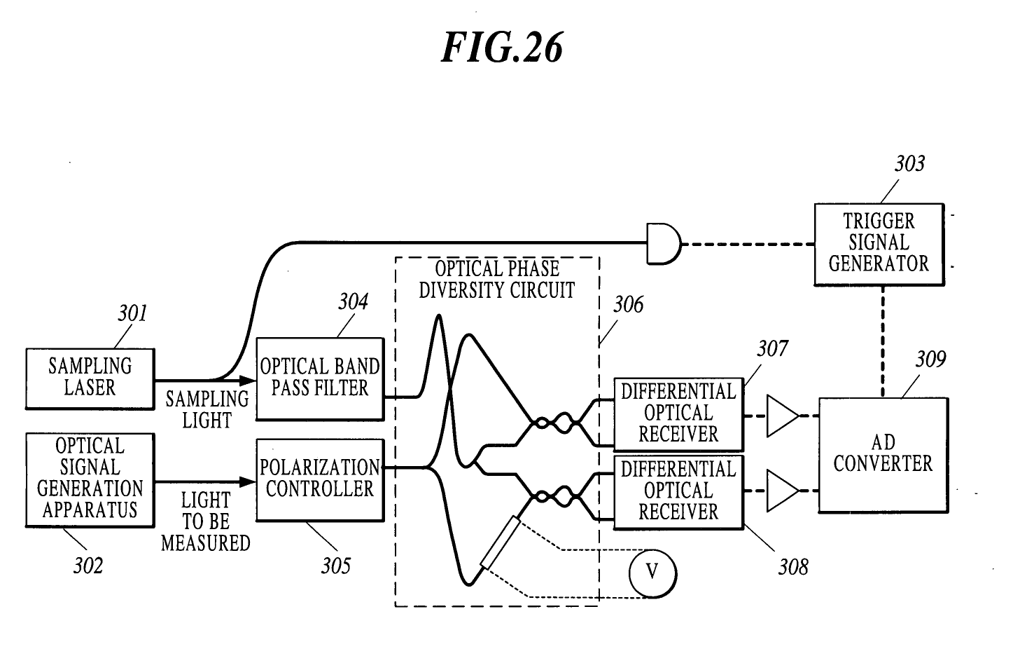

FIG. 27 is a diagram showing the configuration of the optical phase diversity circuit of FIG. 26; and

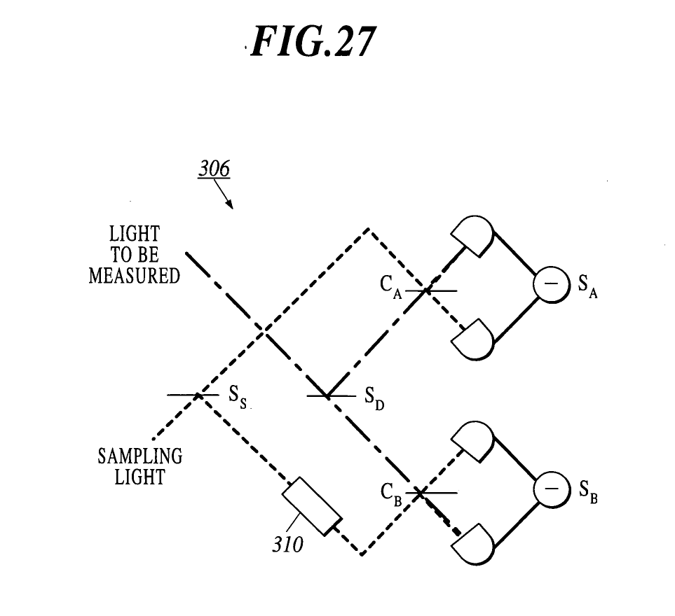

FIG. 28 is a diagram showing an example of an amplitude phase distribution.

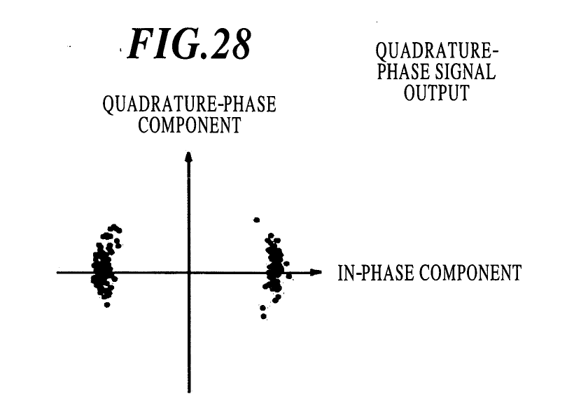

### DETAILED DESCRIPTION OF THE PREFERRED EMBODIMENTS

In the following, a first to a fourth embodiments of the present invention will be described with reference to the attached drawings.

### First Embodiment

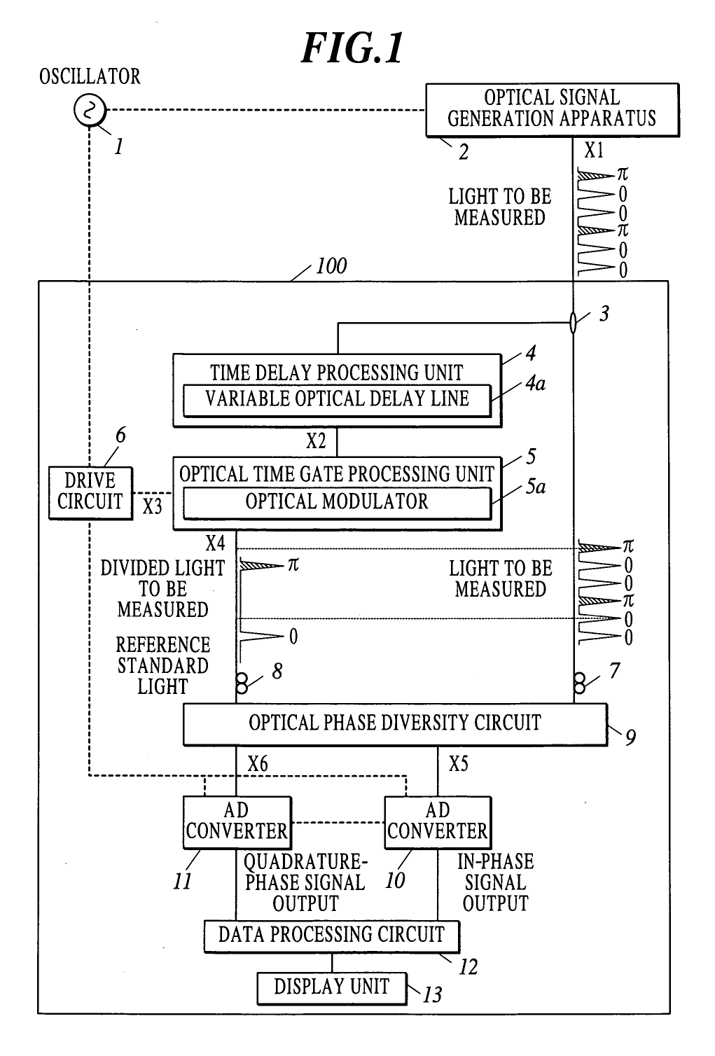

The first embodiment of the present invention will be described with reference to FIGS. 1-16.

FIG. 1 shows an example of the internal configuration of a light measurement apparatus 100 according to the first embodiment, an oscillator 1 and an optical signal generation apparatus 2.

The oscillator 1 outputs an electric clock signal synchronized with the light to be measured that is generated by the optical signal generation apparatus 2 to the optical signal generation apparatus 2 and a drive circuit 6 of the light measurement apparatus 100.

The optical signal generation apparatus 2 supposes an optical signal on which data propagating through an actual transmission path is superimposed, and generates the light to be measured on which random data is superimposed in synchronization with the electric clock signal input from the oscillator 1. As the light to be measured on which the random data is superimposed, for example, an optical signal that is modulated by the DPSK system is cited.

The light measurement apparatus 100 is composed of an optical branching device 3, a time delay processing unit 4, an optical time gate processing unit 5, the drive circuit 6, polarization controllers 7 and 8, an optical phase diversity circuit 9, AD converters 10 and 11, a data processing circuit 12 and a display unit 13, as shown in FIG. 1.

The optical branching device 3 branches the light to be measured that is input from the optical signal generation apparatus 2 into two pieces.

The time delay processing unit 4 includes a variable optical delay line 4a, and gives one piece of the light to be measured that has been branched by the optical branching device 3 a time delay. The time delay processing unit 4 adjusts the variable optical delay line 4a so that a relative time difference between the light to be measured that is input into the optical phase diversity circuit 9 and reference standard light (that will be described later) may be an m bit time (m is an integer).

The optical time gate processing unit 5 is composed of an optical modulator 5a (for example, an electroabsorption optical modulator), and performs the processing of extracting the one piece of the light to be measured that has been branched by the optical branching device 3 every n bit time (n is an integer). In the following, the optical signal that has been processed by the optical time gate processing unit 5 is referred to as the reference standard light (or as divided light to be measured). In addition, in the light measurement apparatus 100 of FIG. 1, there is shown the case where the time delay processing unit 4 is arranged at the preceding stage of the optical time gate processing unit 5, and where the optical time gate processing is performed to the light to be measured that has been given a time delay by the time delay processing unit 4. But, the time delay processing unit 4 may be arranged at the subsequent stage of the optical time gate processing unit 5.

The drive circuit 6 generates a drive signal having a period longer than the repetition period of the light to be measured based on the electric clock signal input from the oscillator 1, and drives the optical modulator 5a included in the optical time gate processing unit 5 with the drive signal. Moreover, the drive circuit 6 further outputs a drive signal to the AD converters 10 and 11.

The polarization controller 7 adjusts the polarization of the other piece of the light to be measured that has been branched by the optical branching device 3. The polarization controller 8 adjusts the polarization of the reference standard light.

The optical phase diversity circuit 9 is also called as a 90° optical hybrid, and outputs the in-phase signal component and the quadrature-phase signal component of the input light to be measured to the AD converters 10 and 11, respectively, by the interference of the light to be measured and the reference standard light that has been input into the optical phase diversity circuit 9.

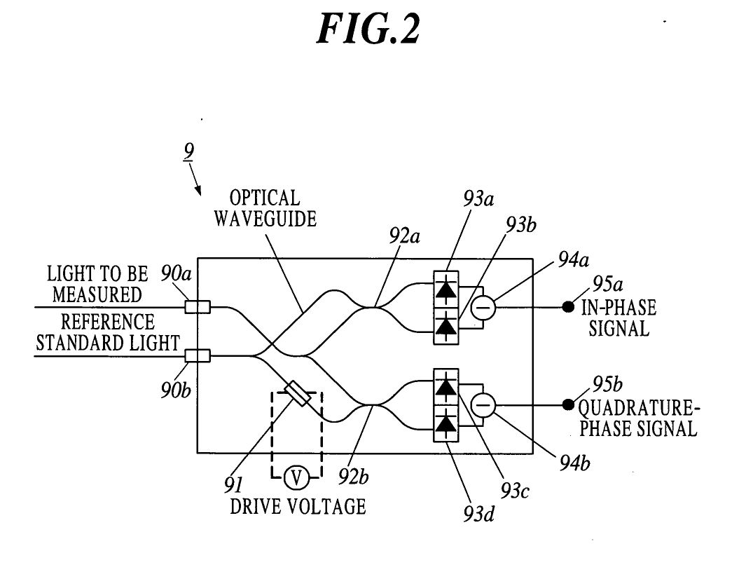

FIG. 2 shows an example of the internal configuration of the optical phase diversity circuit 9. The optical phase diversity circuit 9 shown in FIG. 2 is composed of a light to be measured input port 90a, a reference standard light input port 90b, a voltage-driven phase adjustor 91, directional couplers 92a and 92b, light receiving elements (photodetectors) 93a, 93b, 93c and 93d, differential output circuits 94a and 94b, an in-phase signal output port 95aand a quadrature-phase signal output port 95b.

The light to be measured input through the light to be measured input port 90a is branched into two pieces, and the reference standard light input through the reference standard light input port 90b is also branched into two pieces. One piece of the branched light to be measured is input into the directional coupler 92a to be branched into two pieces, and each of the branched pieces is input into the light receiving elements 93a and 93b, respectively. Moreover, one piece of the branched reference standard light is also input into the directional coupler 92a to be branched into two pieces, and each of the branched pieces is input into the light receiving elements 93a and 93b, respectively.

In the light receiving elements 93a and 93b, the input optical signals are converted into electric signals. At this time, because the light to be measured and the reference standard light that have been input into the light receiving element 93a interfere with each other, an interference signal (including a direct-current component) according to a relative phase difference φ of both of them is output from the light receiving element 93a. Also in the light receiving element 93b, a similar interference signal can be obtained, but the interference signal having the inverted intensity to that of the output signal of the light receiving element 93a can be obtained owing to the characteristic of the directional coupler 92a.

The differential output circuit 94a calculates the difference between the output signals of the two light receiving elements 93a and 93b, and outputs the calculated difference. Consequently, the direct-current component is removed from the two interference signals, and then only the interference signal according to the phase difference φ is output from the in-phase signal output port 95a as the electric signal.

On the other hand, the other piece of the branched reference standard light is input into the directional coupler 92b after the phase difference of π/2 has been added to the other piece by the phase adjustor 91. Moreover, also the other piece of the branched light to be measured is input into the directional coupler 92b. The light to be measured and the reference standard light that have been branched by the directional coupler 92b are input into the light receiving elements 93c and 93d, and an interference signal according to the relative phase difference of them of φ+π/2 can be obtained by the differential output circuit 94b as the electric signal. Then, the interference signal is output from the quadrature-phase signal output port 95b.

Because the output signal from the differential output circuit 94a and the output signal from the differential output circuit 94b become the signal components perpendicular to the phase of the light to be measured, one of them is obtained as the in-phase signal component, and the other of them is obtained as the quadrature-phase signal component. Then, the data processing of them is performed in the data processing circuit 12 after the conversion into digital signals.

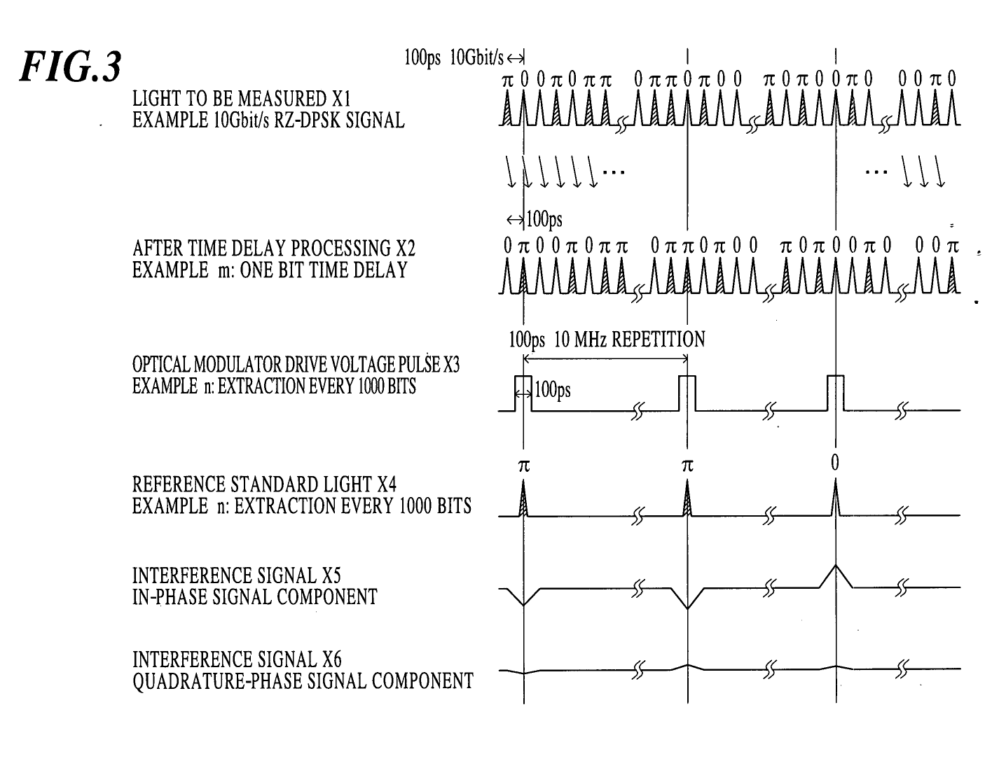

FIG. 3 shows a time chart of light to be measured X1 generated in the optical signal generation apparatus 2, light to be measured X2 that has been given a time delay by the time delay processing unit 4, a drive signal (drive voltage pulse) X3 output from the drive circuit 6, reference standard light X4 output from the optical time gate processing unit 5, and the in-phase signal component X5 of the light to be measured and the quadrature-phase signal component X6 that are output from the optical phase diversity circuit 9.

As shown in FIG. 3, when an RZ-DPSK signal of 10 Gbit/s (repetition frequency 10 GHz) is used as the light to be measured X1 and the light to be measured X1 is extracted for a 1000 bit time (n=1000), the drive signal of the optical modulator 5a becomes a repetition pulse train of 10 MHz (the interval of 100 ns). Moreover, if it is supposed that the relative time difference between the light to be measured X1 and the reference standard light X4 is one bit time (m=1) to the light to be measured X1 of 10 Gbit/s, the relative time difference becomes 100 ps. Under such supposition, the interference signals (beat signals) X5 and X6 between different m bits of the light to be measured are obtained from the optical phase diversity circuit 9 as the electric signals.

The AD converters 10 and 11 convert the in-phase signal component and the quadrature-phase signal component of the light to be measured that have been input from the optical phase diversity circuit 9 into digital signals, respectively, and outputs the converted digital signals to the data processing circuit 12.

The data processing circuit 12 successively calculates at least one of the amplitude variation and the phase variation between different m bits of the light to be measured at the repetition period (n bit time) of the reference standard light by analyzing the data input from the AD converters 10 and 11. Moreover, the data processing circuit 12 produces an amplitude phase distribution from the obtained measurement values to output the display data of the produced amplitude phase distribution to the display unit 13.

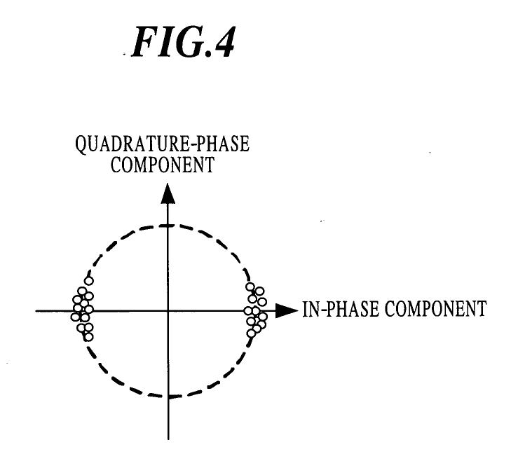

The display unit 13 is composed of a display such as a liquid crystal display (LCD), and the like, and displays the processing results of the data processing circuit 12. To put it concretely, the display unit 13 displays the amplitude phase distribution produced by the data processing circuit 12. FIG. 4 shows an example of the amplitude phase distribution of an RZ-DPSK signal. The statistical distribution of the amplitude variation and the phase variation of the light to be measured can be obtained from the dispersion of the plotted data of the amplitude phase distribution, and the quality evaluation of the optical signal is enabled.

As described above, the light measurement apparatus 100 of the first embodiment extracts the light to be measured every predetermined bits by the optical time gate processing, and uses one piece of the branched light to be measured as the reference standard light. Consequently, the light measurement apparatus 100 is similarly configured to the conventional technique that likens the reference standard light as the sampling light. However, because the light measurement apparatus 100 is configured to be a self-homodyne interferometer using the light to be measured itself as the reference standard light, an interference signal can be always obtained independent of the wavelength of the light to be measured, and it becomes possible to perform the amplitude measurement and the phase measurement steadily. Moreover, because the light measurement apparatus 100 does not need to prepare any local light (sampling light) unlike the conventional technique, no measurement errors caused by the stability of the local light are generated.

Moreover, because the light measurement apparatus 100 is a self-homodyne interferometer, a measurement value is a relative value between bits. However, the absolute value of the measurement value can be also estimated by numerical calculation. Moreover, because the light measurement apparatus 100 is configured to conform to a delay interferometer, the light measurement apparatus 100 has good consistency with a differential phase modulation method using a delay interferometer as a signal receiver, and the Q value measurement of a differential phase-modulated signal and the measurement of a bit error rate become possible.

In addition, the description contents pertaining to the first embodiment can be suitably changed without departing from the sprit of the present invention.

For example, as the optical modulator used in the optical time gate processing unit, a waveguide type Mach-Zender interferometric modulator using LiNbO₃ crystal can be also used. Moreover, a high speed optical switch (such as one using light interference, one using the absorption/ transmission of light power, one using the reflection/transmission of light power or the like) can be also used in place of the optical modulator. Moreover, an external light control type modulator/switch (using an optical Kerr shutter or a saturable absorber) can be also used for the optical time gate processing unit 5. Moreover, if the processing by the optical modulator 5a is insufficient, it is also possible to configure the used device to be a multistage configuration.

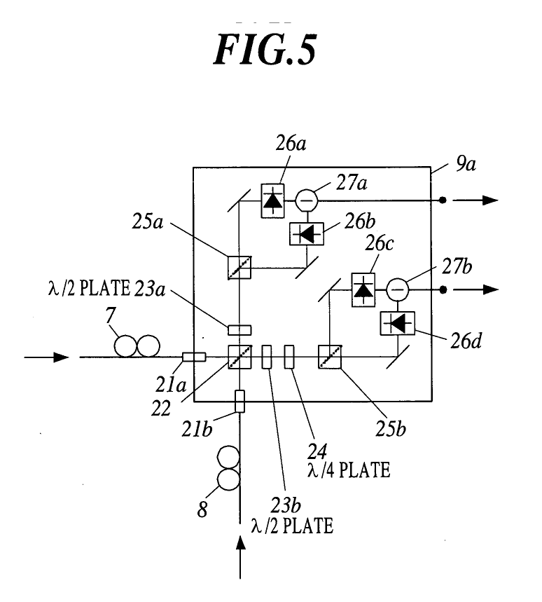

Moreover, although FIG. 2 shows the waveguide type optical phase diversity circuit 9, it is also possible to use a space system optical element. FIGS. 5-7 show examples of the internal configurations of the optical phase diversity circuits using space system optical elements.

An optical phase diversity circuit 9a shown in FIG. 5 is composed of input ports (collimators) 21a and 21b, an optical branching device 22, λ/2 plates (half-wave plates) 23a and 23b, a λ/4 plate (quarter-wave plate) 24, polarization beam splitters 25a and 25b, light receiving elements 26a, 26b, 26c and 26d, and differential output circuits 27a and 27b.

The light to be measured that has been input through the input port (collimator) 21a is branched into two pieces by the optical branching device 22. At this time, the light to be measured input into the optical branching device 22 has been adjusted to be a linearly polarized wave in the horizontal axis direction (or the vertical axis direction) by the polarization controller 7. The direction of the polarization of each of both pieces of the light to be measured that has been branched by the optical branching device 22 is adjusted to be oblique at 45° (or 135°) using the half-wave plate (λ/2 plate 23a or 23b). Respective pieces of the light to be measured that has been changed to the linearly polarized wave being oblique at 45° (or 135°) are branched into two pieces by the polarization beam splitters 25a and 25b, and are input into the light receiving elements 26a, 26b, 26c and 26d.

On the other hand, the reference standard light that has been input through the input port (collimator) 21b is divided into two pieces by the optical branching device 22 similarly to the light to be measured. At this time, the reference standard light entering the optical branching device 22 has been adjusted to be the linearly polarized wave in the vertical axis direction (or the horizontal axis direction) perpendicular to the light to be measured by the polarization controller 8. Each of both pieces of the reference standard light that has been branched by the optical branching device 22 becomes a linearly polarized wave that is oblique at 135° (or 45°) by the half-wave plate (λ/2 plate 23a or 23b). One piece of the reference standard light that has been changed to the oblique linearly polarized wave is branched into two pieces by the polarization beam splitter 25a, and is input into the light receiving elements 26a and 26b. By disposing the λ/4 plate 24 so that the axial direction thereof may agree with the direction of the linearly polarized wave of the reference standard light, the phase of the reference standard light that has become the oblique linearly polarized wave by the λ/2 plate 23b is shifted by π/2 by the λ/4 plate 24, and the shifted reference standard light is branched into two pieces by the polarization beam splitter 25b. Then, the branched reference standard light is input into the light receiving elements 26c and 26d.

The light to be measured and the reference standard light that are input into the light receiving elements 26aand 26b interfere with each other, and an interference signal (including a direct-current component) according to the relative phase difference φ is obtained as the output signal of each of the light receiving elements 26a and 26b. The interference signal obtained by the light receiving element 26a and the interference signal obtained by the light receiving element 26b of the two outputs from the polarization beam splitter 25a are reversed in intensity to each other. Consequently, the direct-current components are removed from both the interference signals by the differential output circuit 27a, and only the interference signal according to the phase difference φ of the light to be measured and the reference standard light is obtained as the electric signal.

The relative phase difference of the light to be measured and the reference standard light that are input into the light receiving elements 26c and 26d becomes φ+π/2 by the operation of the λ/4 plate 24, and an interference signal according to the phase difference can be obtained from the differential output circuit 27b. Because the output signal from the differential output circuit 27a and the output signal from the differential output circuit 27b become the signal components that are severally perpendicular to the phase of the light to be measured, one of them is obtained as the in-phase signal component, and the other of them is obtained as the quadrature-phase signal component. The data processing of these signal components is performed in the data processing circuit 12 after they have been converted into digital signals.

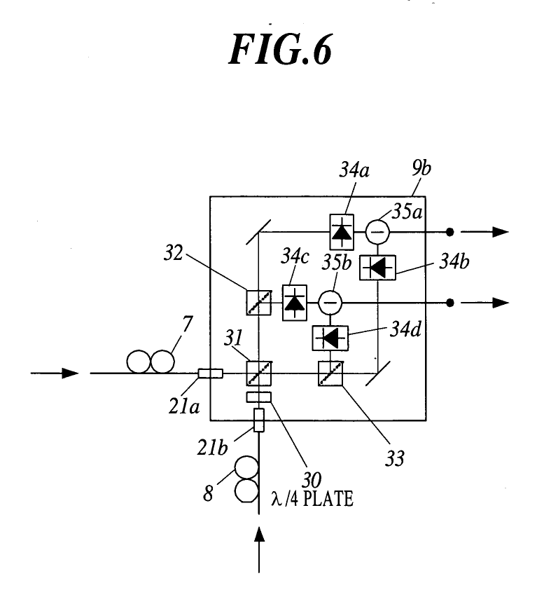

The optical phase diversity circuit 9b shown in FIG. 6 is composed of the input port (collimator) 21a and 21b, a λ/4 plate 30, an optical branching device 31, polarization beam splitters 32 and 33, light receiving elements 34a, 34b, 34c and 34d, and differential output circuits 35a and 35b. The optical phase diversity circuit 9b shown in FIG. 6 takes the configuration in which the λ/2 plates 23a and 23bare removed from the configuration of the optical phase diversity circuit 9a of FIG. 5 and the arrangement of the light receiving elements 34a-34d are different from that of the light receiving elements 26a-26d. The optical phase diversity circuit 9b is similar to the optical phase diversity circuit 9a in principle, and a phase difference is added to the phase of the reference standard light with the λ/4 plate 30. Moreover, both pieces of the light to be measured and the reference standard light are severally changed to a linearly polarized wave of being oblique at 45° (or 135°) to be input.

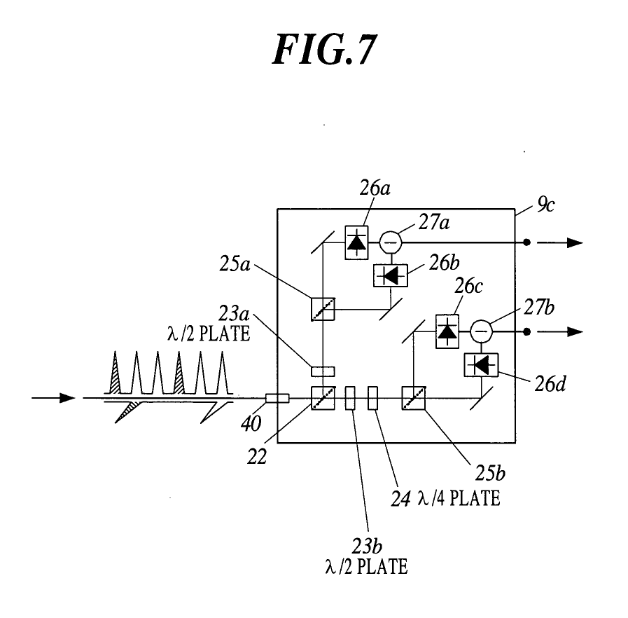

The optical phase diversity circuit 9c shown in FIG. 7 is configured to a form in which the input ports 21a and 21b in the optical phase diversity circuit 9a of FIG. 5 are integrated to be one. By previously adjusting the polarizations of the light to be measured and the reference standard light, the light to be measured and the reference standard light that propagate through the same path are prepared, and the light to be measured and the reference standard light are entered into the optical phase diversity circuit 9c through the input port 40 in the state of being perpendicular polarization to each other.

In the following, modified examples of the light measurement apparatus 100 of the first embodiment are described.

### FIRST MODIFIED EXAMPLE

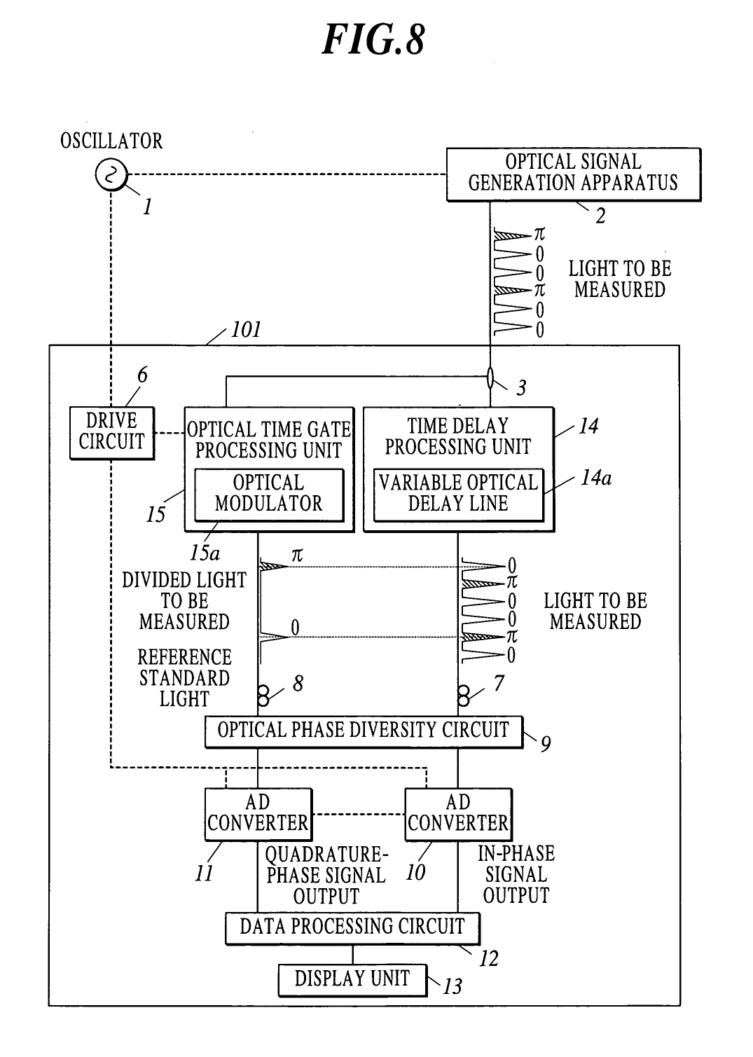

Although the case where the time delaying processing and the optical time gate processing are performed to one piece of the light to be measured branched by the optical branching device 3 has been shown in the light measurement apparatus 100 of FIG. 1, a time delay may be given to one piece of the light to be measured branched by the optical branching device 3 by a time delay processing unit 14 including a variable optical delay line 14a, and the optical time gate processing may be performed to the other piece of the branched light to be measured by an optical time gate processing unit 15 including an optical modulator 15a, as shown in a light measurement apparatus 101 of FIG. 8.

### SECOND MODIFIED EXAMPLE

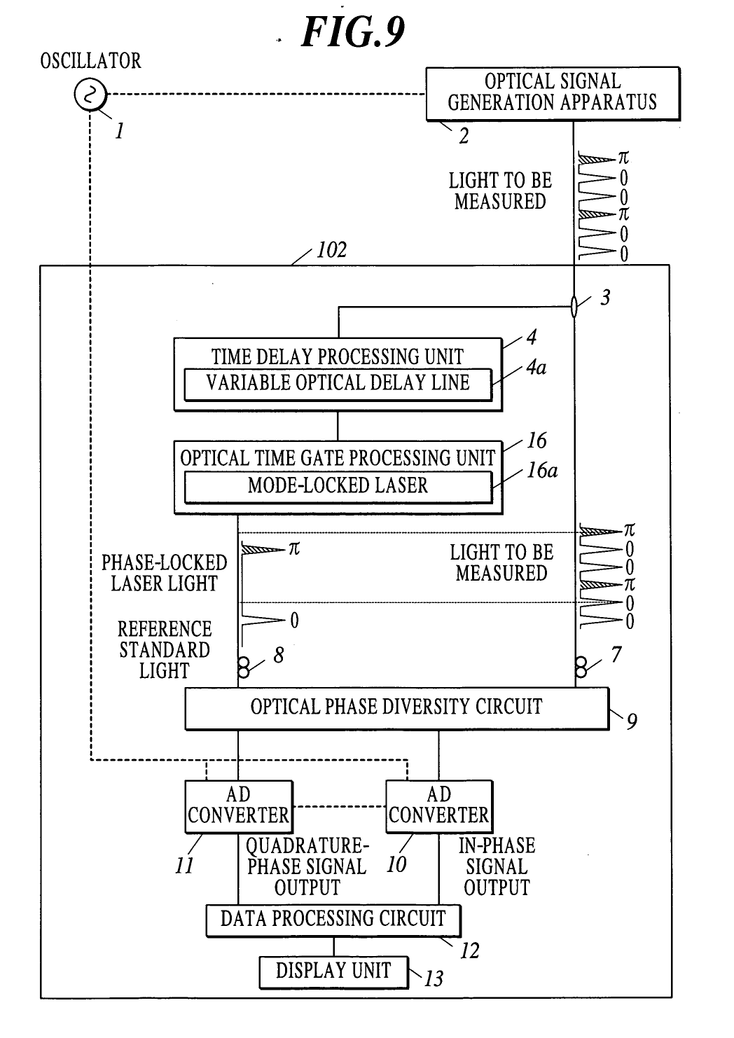

An optical time gate processing unit 16 of a light measurement apparatus 102 shown in FIG. 9 performs the optical time gate processing by a mode-locked laser 16a. The mode-locked laser 16a uses a light injection locking technique using the light to be measured as a trigger of laser oscillation. Because the laser light obtained by the light injection locking is in the same phase state as the phase of the light to be measured, which is the trigger, the laser light can be used as the reference standard light.

### THIRD MODIFIED EXAMPLE

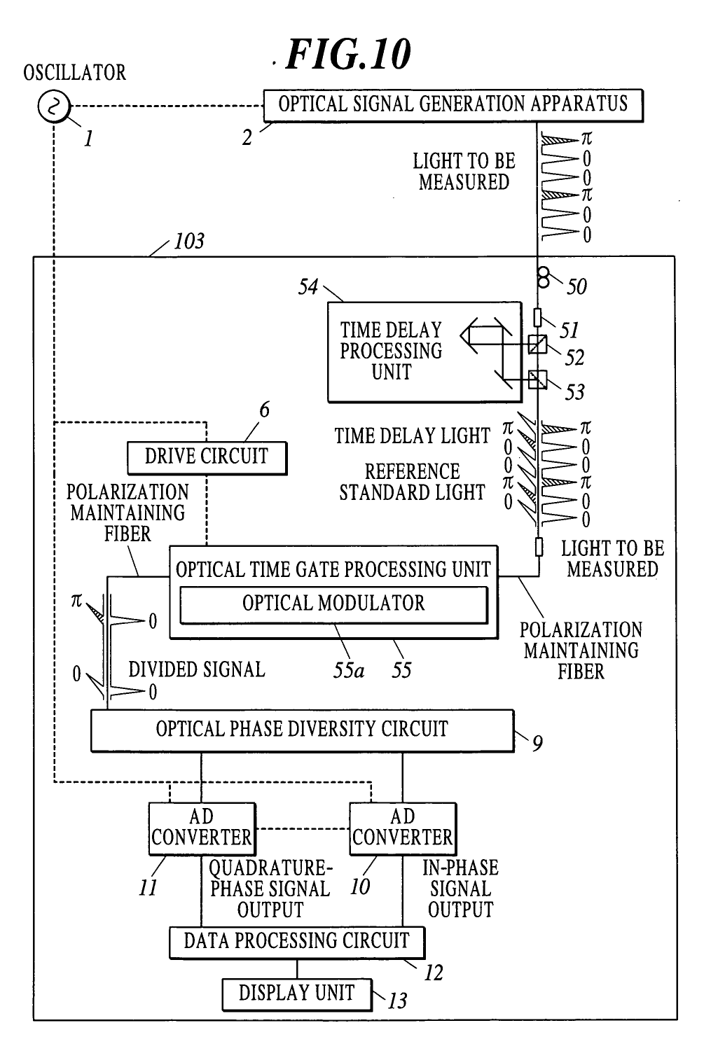

In a light measurement apparatus 103 shown in FIG. 10, the light to be measured that has received polarization adjustment by a polarization controller 50 and has been input through a collimator 51 is branched into two pieces by an optical branching device 52 (polarization beam splitter). One piece of the branched light to be measured receives the time delaying processing by a time delay processing unit 54 including four mirrors, and then is multiplexed with the other piece of the branched light to be measured by a multiplexer 53. After that, the multiplexed light receives the optical time gate processing in a lump by an optical time gate processing unit 55 including an optical modulator 55a.

In the light measurement apparatus 103, the multiplexed light to be measured and the reference standard light to which a time delay has been given propagate in the same polarization maintaining fiber. The polarization maintaining fiber is different from a general single mode fiber, and is an optical fiber having different propagation characteristics in the X axis and the Y axis that are perpendicular to the Z axis that is supposed to be the lengthwise direction of the fiber. When the light of a linearly polarized wave is input with the polarization axis thereof being adjusted to the X axis (or the Y axis) of an optical fiber, the light propagates in the optical fiber with the polarization state being kept, and the light of X polarization (or Y polarization) can be obtained even at the exit end. In the light measurement apparatus 103, for example, it is possible to propagate the light to be measured as an X polarization and the reference standard light that has been given a time delay as a Y polarization through the same polarization maintaining fiber.

In the light measurement apparatus 103, it can be considered that the noises at the time of light reception is reduced because the optical time gate processing unit 55 extracts the light to be measured and the reference standard light that has been given the time delay at the same time and inputs only the optical signal necessary for data acquisition into the optical phase diversity circuit 9.

### FOURTH MODIFIED EXAMPLE

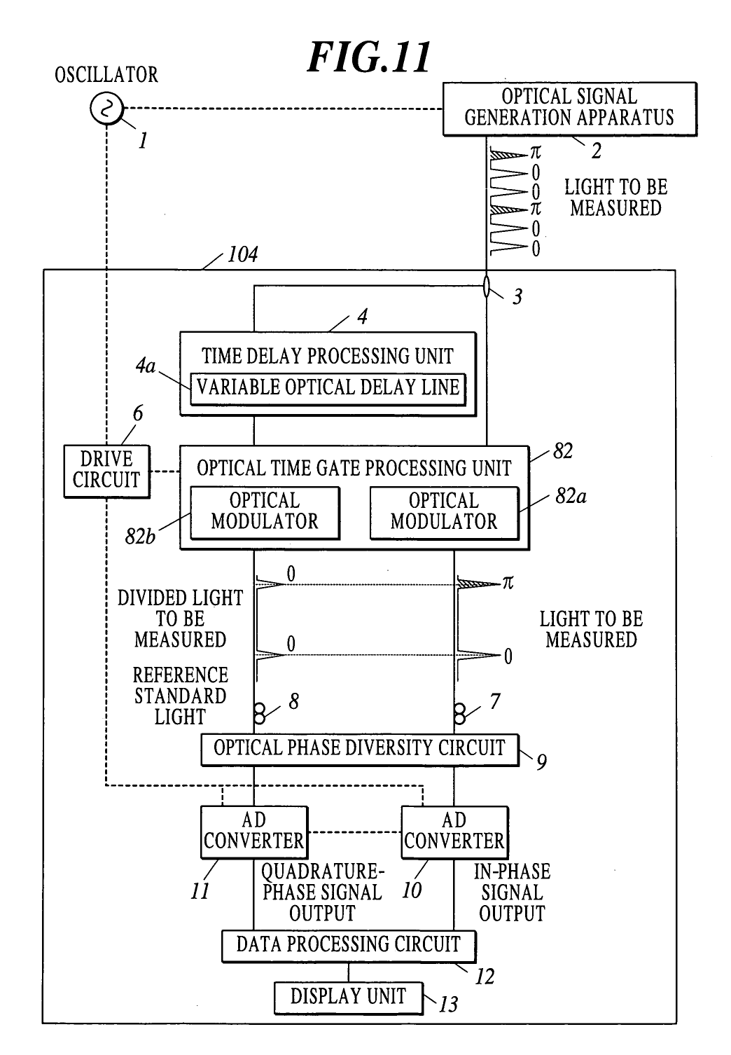

A light measurement apparatus 104 shown in FIG. 11 is configured as follows. That is, two optical modulators 82aand 82b are arranged in parallel in an optical time gate processing unit 82, and the processing of extracting different bits is performed to each piece of the light to be measured that has been branched into two pieces by the optical branching device 3. Then, an interference signal between different bits is obtained by the optical phase diversity circuit 9. It is considered that, also in the fourth modified example, because only the optical signal necessary for data acquisition is input into the optical phase diversity circuit 9 similarly to the third modified example, the noises at the time of light reception is reduced.

### FIFTH MODIFIED EXAMPLE

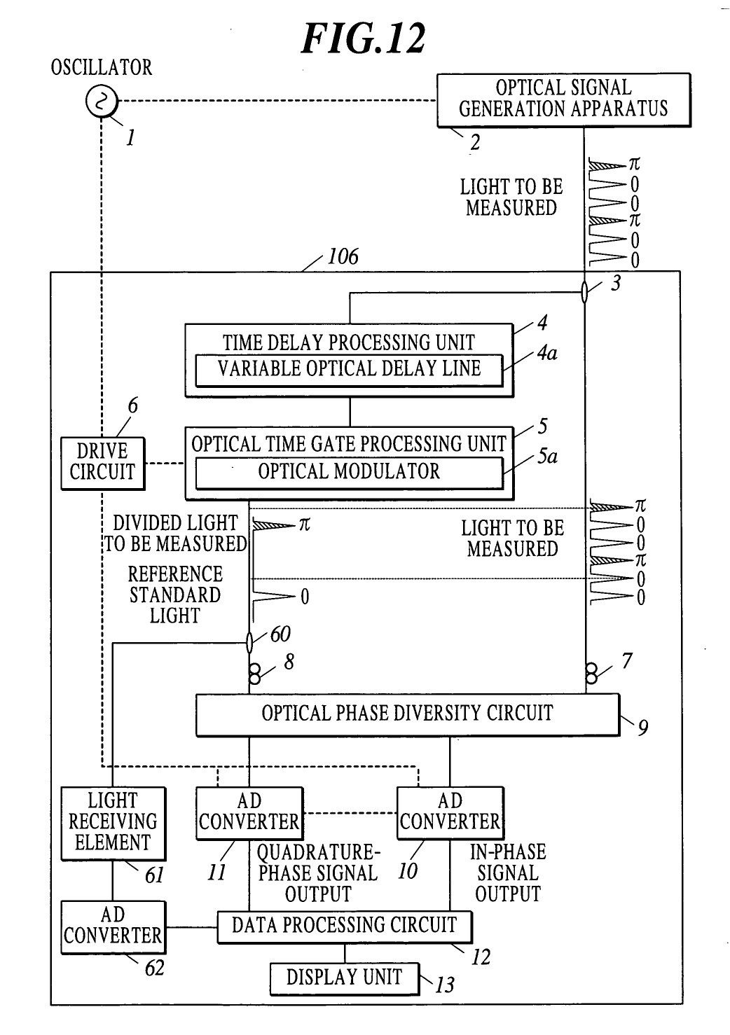

A light measurement apparatus 106 shown in FIG. 12 is configured as follows. That is, an optical branching device 60 is disposed at the subsequent stage of the optical time gate processing unit 5, and one piece of the reference standard light branched by the optical branching device 60 is converted into an electric signal by a light receiving element 61, and the converted electric signal (analog signal) is converted into a digital signal by an AD converter 62. Then, the digital signal is output to the data processing circuit 12. With such a configuration, the intensity of the reference standard light is separately (separately from amplitude phase measurement) measured to use the measured intensity for data processing. Thereby, it becomes possible to improve the measurement accuracy. Moreover, it is also possible to measure a modulated signal (for example a signal modulated by the APSK system) composed of a digital value added to the intensity (amplitude) component of an optical signal. In addition, the measurement means of the present invention corresponds to the light receiving element 61 and the AD converter 62. Moreover, although the configuration of FIG. 12 is one to measure the intensity of the reference standard light, the one to measure not the intensity of the reference standard light but the intensity of the light to be measured to use the measured intensity for data processing may be adopted. That is, as long as a configuration uses the intensity of at least one of the reference standard light and the light to be measured for data processing, the configuration may be adopted.

### SIXTH MODIFIED EXAMPLE

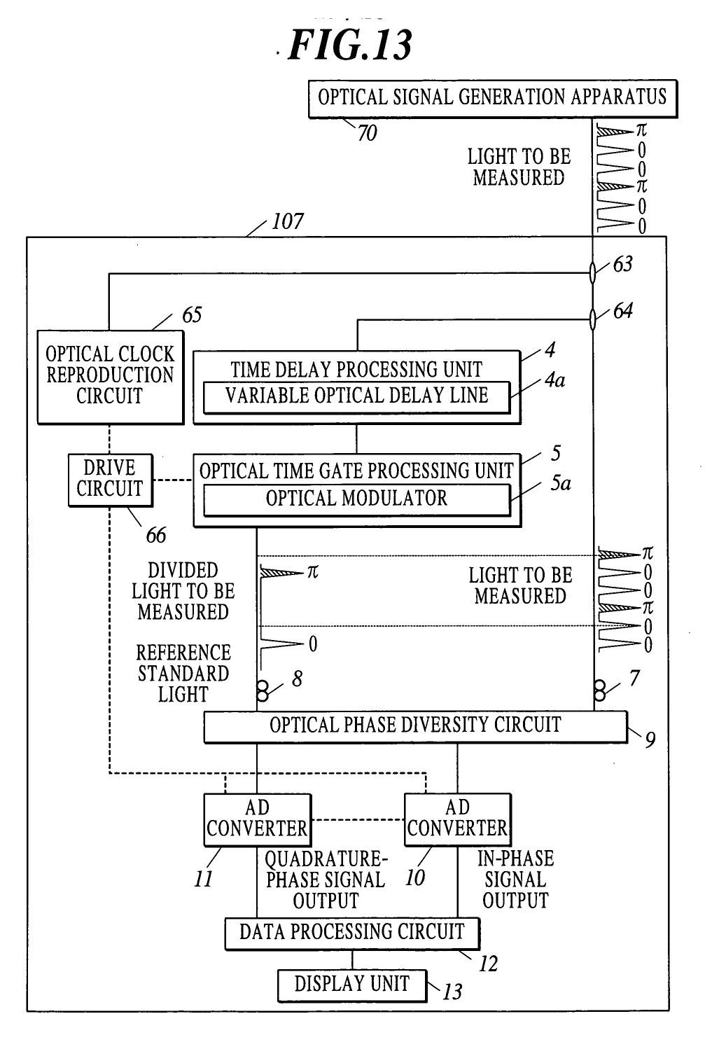

In a light measurement apparatus 107 shown in FIG. 13, an optical signal generation apparatus 70 generates the light to be measured (for example, an optical signal modulated by the DPSK system) on which random data is superimposed, and an optical branching device 63 branches the generated light to be measured. An optical clock recovery circuit 65 generates an electric clock signal synchronizing with one piece of the light to be measured that has been branched by the optical branching device 63, and outputs the generated electric clock signal to the drive circuit 66. The drive circuit 66 generates a drive signal having a period longer than the repetition period of the light to be measured based on the electric clock signal input from the optical clock recovery circuit 65, and drives the optical modulator 5a included in the optical time gate processing unit 5 by means of the generated drive signal. The other piece of the light to be measured branched by the optical branching device 63 is further branched by an optical branching device 64, and time delaying processing and optical time gate processing are performed to one piece of the further branched light to be measured.

As described above, the light measurement apparatus 107 is provided with the optical clock recovery circuit 65, and consequently the light measurement apparatus 107 does not need to be equipped with any oscillators to generate the electric clock signal synchronizing with the light to be measured. In addition, the optical signal used for clock recovery may be taken out from the subsequent stage of the optical branching device 64.

### SEVENTH MODIFIED EXAMPLE

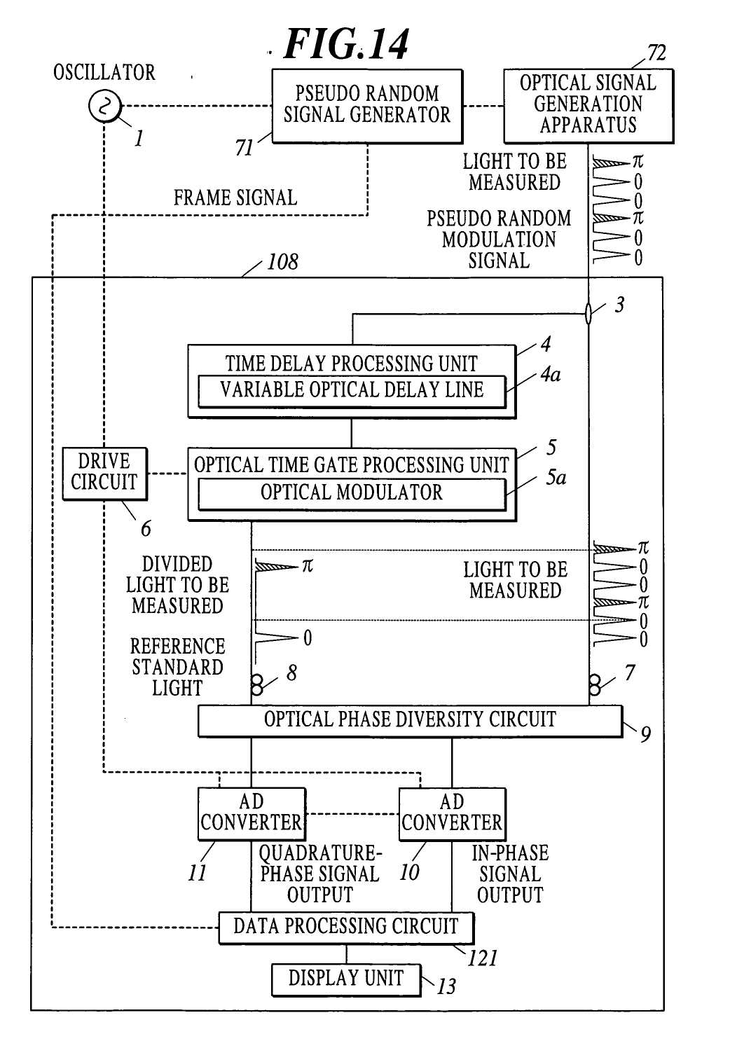

In a light measurement apparatus 108 shown in FIG. 14, an optical signal on which pseudo random data is superimposed (pseudo random modulation signal) is used as the light to be measured. In FIG. 14, a pseudo random signal generator 71 outputs a signal (a pseudo random signal) corresponding to a pseudo random code to an optical signal generation apparatus 72. Moreover, the pseudo random signal generator 71 generates a frame signal synchronizing with the repetition frequency of the pseudo random code, and outputs the generated frame signal to a data processing circuit 121 of the light measurement apparatus 108. The optical signal generation apparatus 72 generates a pseudo random modulation signal as the light to be measured based on the pseudo random signal input from the pseudo random signal generator 71.

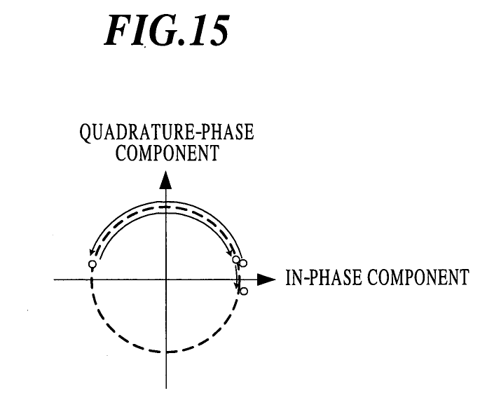

The data processing circuit 121 rearranges the acquisition data from the AD converters 10 and 11 using the frame signal input from the pseudo random signal generator 71 as a reference, and thereby calculates the amplitude variation and the phase variation of each bit of the light to be measured. The display unit 13 devises the display of an amplitude phase distribution to make it possible to display the locus of amplitude change and phase change of the light to be measured as shown in FIG. 15, or to display the movement of the changes dynamically (as an animation).

### EIGHTH MODIFIED EXAMPLE

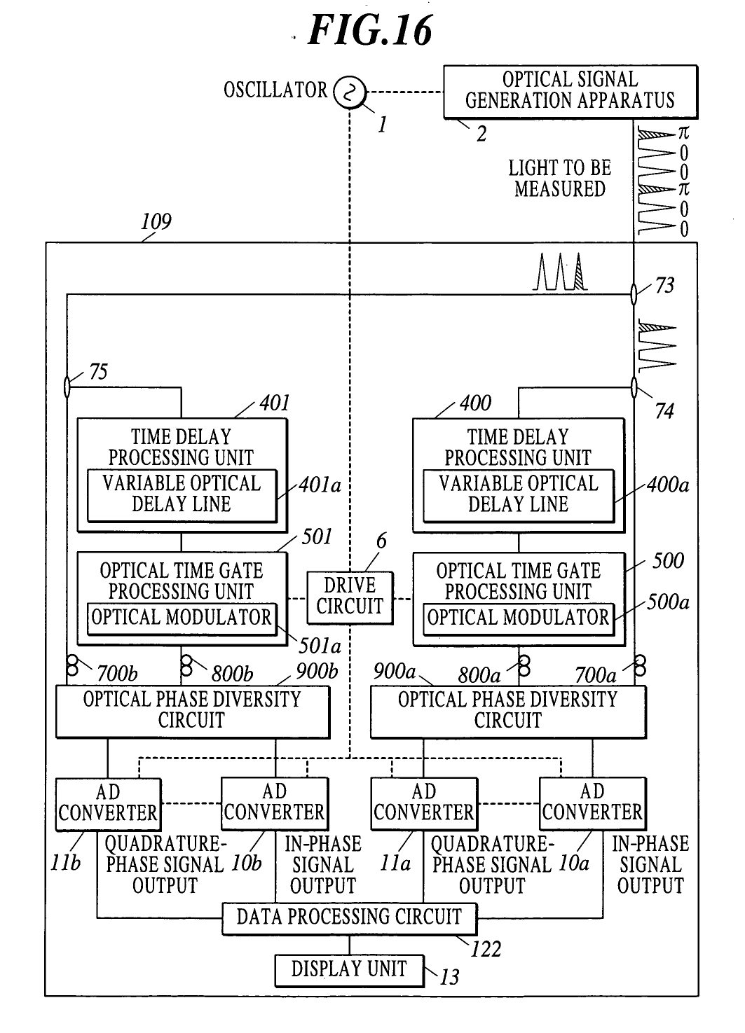

A light measurement apparatus 109 shown in FIG. 16 has the configuration to split light to be measured into two polarization components perpendicular to each other with a polarization split device 73, and to perform the amplitude measurement and the phase measurement of each of the polarization components independently after the split based on the same principle as that of the light measurement apparatus 100 of FIG. 1. The in-phase signal component and the quadrature-phase signal component of one polarization component are obtained using an optical branching device 74, a time delay processing unit 400 including a variable optical delay line 400a, an optical time gate processing unit 500 including an optical modulator 500a, polarization control units 700a and 800a, an optical phase diversity circuit 900a, and AD converters 10a and 11a. The in-phase signal component and the quadrature-phase signal component of the other polarization component are similarly obtained using an optical branching device 75, a time delay processing unit 401 including a variable optical delay line 401a, an optical time gate processing unit 501 including an optical modulator 501a, polarization control units 700b and 800b, an optical phase diversity circuit 900b, and AD converters 10b and 11b.

A data processing circuit 122 analyzes the acquisition data from the AD converters 10a, 11a, 10b and 11b to make it possible to calculate the polarization state of the light to be measured. The display unit 13 can obtain two kinds of amplitude phase distributions according to polarization. By applying the light measurement apparatus 109 of the eighth modified example, the measurement that does not depend on an input polarization state (polarization diversifying) becomes possible.

### Second Embodiment

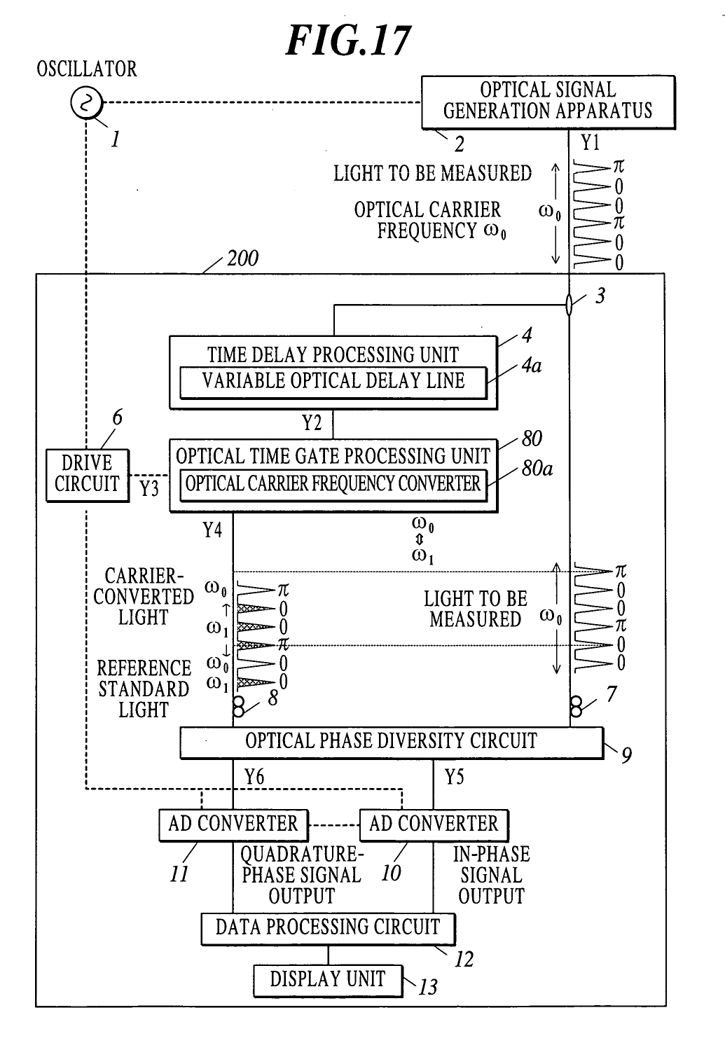

With reference to FIGS. 17-20, a second embodiment of the present invention is described.

In the second embodiment, an optical carrier frequency (wavelength) converter is used.

FIG. 17 shows an example of the internal configuration of a light measurement apparatus 200 according to the second embodiment. In addition, in the second embodiment, the same constituent elements as those of the light measurement apparatus 100 of the first embodiment are denoted by the same marks as those of the first embodiment. In the following, only the respects different from those of the light measurement apparatus 100 of the first embodiment are described.

The light measurement apparatus 200 is composed of the optical branching device 3, the time delay processing unit 4, an optical time gate processing unit 80, the drive circuit 6, the polarization controllers 7 and 8, the optical phase diversity circuit 9, the AD converters 10 and 11, the data processing circuit 12 and the display unit 13, as shown in FIG. 17.

The drive circuit 6 generates a drive signal having a period longer than the repetition period of light to be measured based on an electric clock signal input from the oscillator 1, and drives an optical carrier frequency converter 80a included in the optical time gate processing unit 80 by the drive signal. Moreover, the drive circuit 6 further outputs a drive signal to the AD converters 10 and 11.

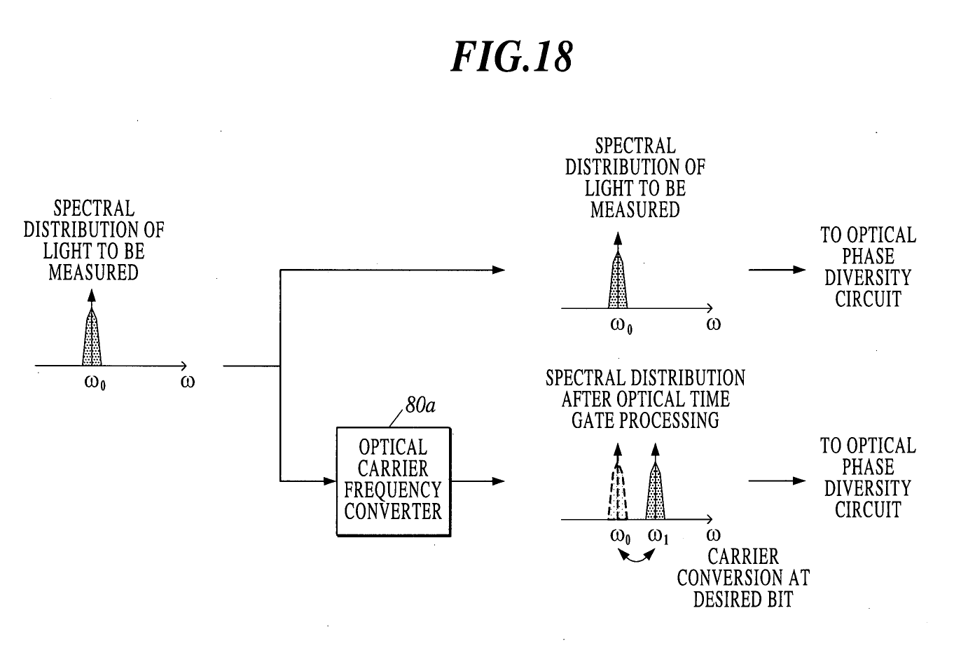

The optical time gate processing unit 80 is composed of the optical carrier frequency converter 80a (for example, a modulator of optical frequency shift keying (FSK)). The optical carrier frequency converter 80a is a device that does not change any light intensity but changes the optical carrier frequency (or wavelength) of an optical signal (light to be measured), and can perform the mutual conversion of different optical carrier frequencies (ω₀ and ω₁) by the drive signal from the drive circuit 6 as shown in FIG. 18. To put it concretely, the optical carrier frequency converter 80a operates by the drive signal having the period longer than the repetition period of the light to be measured, and thereby performs the processing of switching the optical carrier frequency of the light to be measured every n bit time (n is an integer). In the following, the output signal of the optical carrier frequency converter 80a is referred to as reference standard light (or carrier conversion light).

The time delay processing unit 4 adjusts the variable optical delay line 4a so that, for example, the relative time difference between the light to be measured and the reference standard light that will be input into the optical phase diversity circuit 9 may be m bit time (m is an integer). In addition, although the case where the time delay processing unit 4 is disposed at the preceding stage of the optical time gate processing unit 80 is shown in the light measurement apparatus 20b of FIG. 17, the time delay processing unit 4 may be disposed at the subsequent stage of the optical time gate processing unit 80.

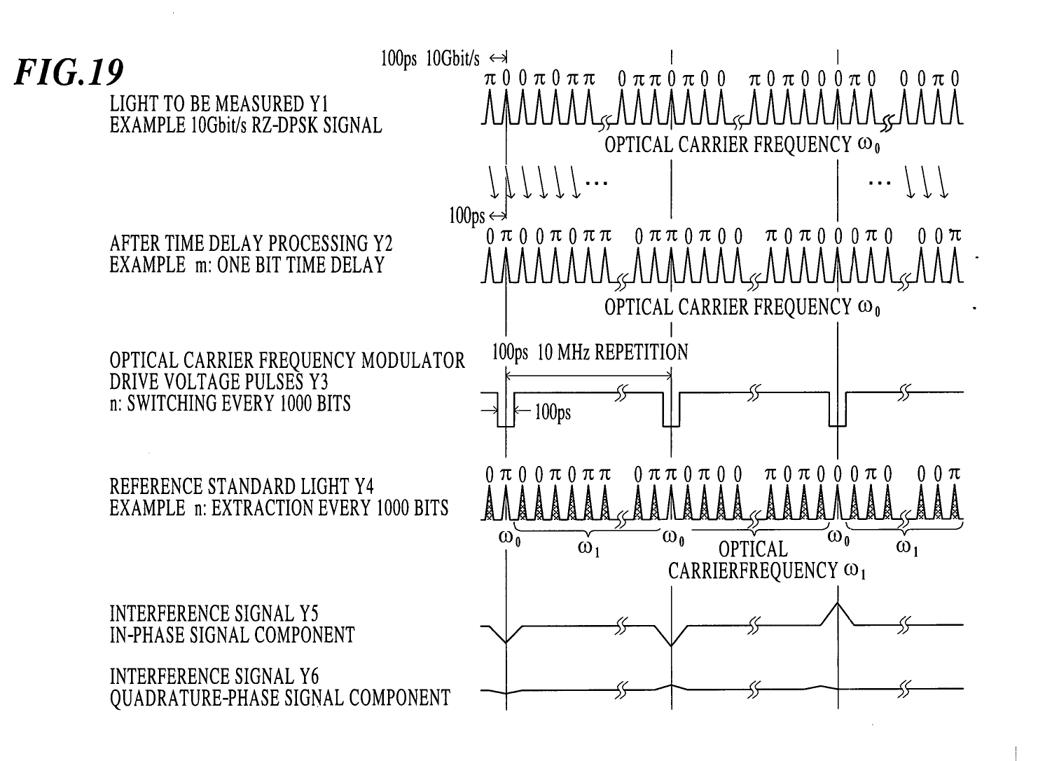

FIG. 19 shows a time chart of light to be measured Y1 generated by the optical signal generation apparatus 2, light to be measured Y2 that has been given a time delay by the time delay processing unit 4, a drive signal Y3 output from the drive circuit 6, reference standard light Y4 output from the optical carrier frequency converter 80a, an in-phase signal component Y5 of the light to be measured output from the optical phase diversity circuit 9, and a quadrature-phase signal component Y6.

It is supposed that the optical carrier frequency of the light to be measured is ω₀ and is fixed independent of the bits of a signal. Moreover, it is supposed that optical carrier frequency converter 80a converts the optical carrier frequency of a desired bit of every n bit time to ω₀ and the optical carrier frequencies of the other bits to ω₁. As shown in FIG. 19, when the RZ-DPSK signal of 10 Gbit/s (repetition frequency 10 GHz) is used as the light to be measured Yl and the optical carrier frequency of the light to be measured Y1 is switched every 1000 bit time (n=1000), the light to be measured becomes the light the optical carrier frequency of which is ω₀ every 10 MHz (the interval of 100 ns). Moreover, if it is supposed that the relative time difference between the light to be measured Yl and the reference standard light Y4, which are input into the optical phase diversity circuit 9, is one bit time (m=1) to the light to be measured Y1 of 10 Gbit/s, the relative time difference becomes that of 100 ps. The input light to be measured Y1 and the reference standard light Y4 are made to interfere with each other in the optical phase diversity circuit 9, and the interference signals (beat light) Y5 and Y6 can be obtained as electric signals by the light receiving elements and the differential output circuits in the optical phase diversity circuit 9.

When the optical carrier frequencies of the light to be measured and the reference standard light are different from each other, the interference signals become the ones that oscillate according to a frequency difference (ω₀−ω₁). Consequently, when the frequency difference (ω₀−ω₁) becomes large, the obtained interference signals also become high-frequency components. Because the optical phase diversity circuit 9 does not output the signal components with the frequencies of which are equal or higher than the cut-off frequencies of the differential output circuits, the high-frequency components of the interference signals are removed. Accordingly, by operating the optical carrier frequency converter 80a so that the frequency difference (ω₀−ω₁) may be sufficiently large, the interference signals are output only at the bit times when the optical carrier frequencies of the light to be measured and the reference standard light are equal.

Based on the aforesaid principle of operation, the interference signals between different m bits of the light to be measured can be successively obtained in the operation period (n bit time) of the optical carrier frequency converter 80a from the optical phase diversity circuit 9. After that, similarly to the first embodiment, the data acquisition of the in-phase signal output and the quadrature-phase signal output from the optical phase diversity circuit 9 is performed in synchronization with the signal period, and the obtained data is analyzed by the data processing circuit 12. Thereby, the amplitude variations and the phase variations between different m bits of the light to be measured can be successively obtained. Moreover, an amplitude phase distribution is made up based on the obtained measurement values, and the amplitude phase distribution is displayed on the display unit 13. From the dispersion of the plotted data of the amplitude phase distribution, the statistical distribution of the amplitude variations and the phase variations of the light to be measured can be obtained, and the quality evaluation of the optical signal becomes possible.

As described above, according to the light measurement apparatus 200 of the second embodiment, the measurement of the amplitude variation and the phase variation of an optical signal becomes possible without using any local light (sampling light) similarly to the first embodiment.

In the first embodiment, because the optical time gate processing of the light to be measured is performed by the turning on and off of the light intensity, the measurement accuracy is determined by the extinction ratios of the devices to be used. When the amplitude variation and the phase variation of the light to be measured is wanted to be measured at high accuracy, the required specifications of the devices to be used in the optical time gate processing unit become high. Consequently, the devices capable of being used are limited. In the second embodiment, it becomes possible to measure the amplitude variation and the phase variation of the light to be measured using the optical carrier frequency converter based on the principle that is quite different from the turning on and off of the light intensity, and thereby the selection choices of usable devices are widened including the peripheral devices (such as light receiving element) also. Consequently, more flexible construction of a measurement system becomes possible. By such flexibility of system designing, it is possible to enlarge measurement objects and to improve measurement accuracy.

In addition, the description contents in the second embodiment can be suitably changed without departing from the sprit of the present invention.

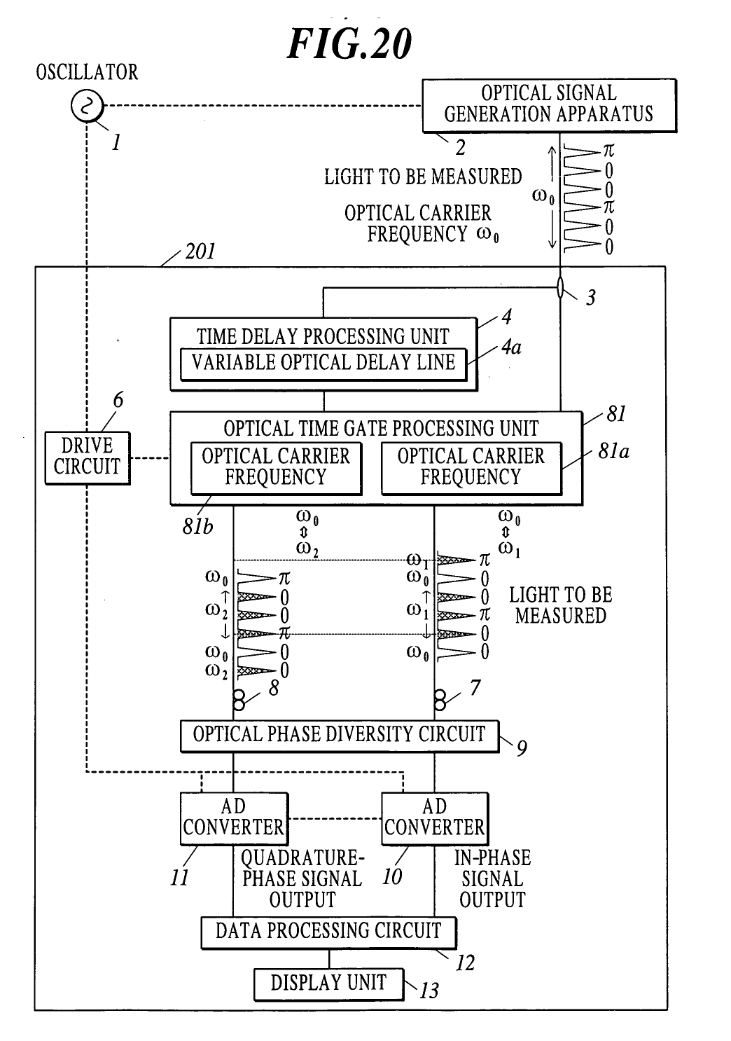

For example, like an optical time gate processing unit 81 of a light measurement apparatus 201 shown in FIG. 20, two optical carrier frequency converters 81a and 81bare arranged in parallel to each other, and each piece of the light to be measured branched into two pieces by the optical branching device 3 is converted to the light having an optical carrier frequency different from each other (ω₁ and ω₂). Thereby, the effect of the signal processing can be redoubled. By such a configuration, the frequency difference (ω₂−ω₁) between two signals that are made to interference with each other in the optical phase diversity circuit 9 can be taken to be large. Consequently, even if the variation of an optical carrier frequency is small, the acquisition of the interference signal of desired bits becomes possible.

Moreover, for example, a semiconductor optical amplifier (SOA) based on the principle of cross gain modulation (XGM) can be also used as the optical carrier frequency converter used in the optical time gate processing unit.

Moreover, a fiber type wavelength conversion switch based on the principle of cross phase modulation (XPM) can be also used as the optical carrier frequency converter.

Moreover, a wavelength conversion switch using the principle based on non-linear optical effects such as sum frequency generation (SFG), differential frequency generation (DFG) and four wave mixing (FWM) can be also used as the optical carrier frequency converter.

Furthermore, when the processing by the optical carrier frequency converter is insufficient, it is also possible that the used devices are configured to be a multistage configuration.

Moreover, also in the second embodiment, the internal configurations shown in FIGS. 2 and 5-7 can be applied as the optical phase diversity circuit 9. Furthermore, also in the light measurement apparatus 200 of the second embodiment, the configurations shown in the respective modified examples of the first embodiment can be applied. In this case, it is sufficient to replace the optical time gate processing unit of the first embodiment with the optical time gate processing unit of the second embodiment.

### Third Embodiment

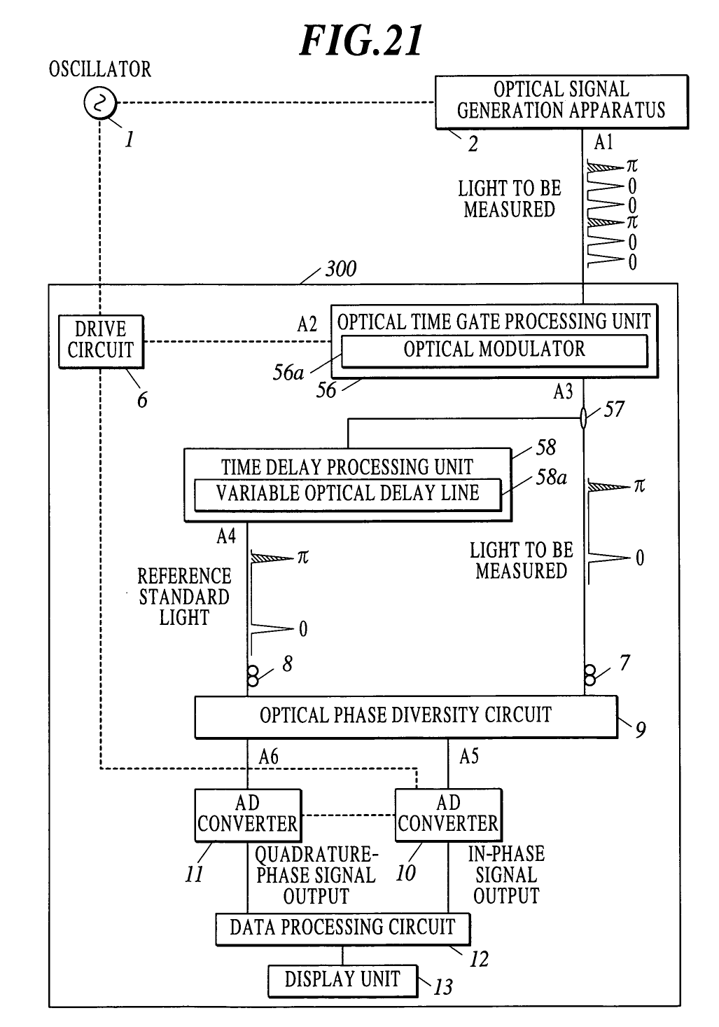

With reference to FIGS. 21-23, a third embodiment of the present invention is described.

In the third embodiment, the dispositions of the optical branching device and the optical time gate processing unit are different from those of the first embodiment.

FIG. 21 shows an example of the internal configuration of a light measurement apparatus 300 according to the third embodiment. In addition, the same constituent elements of the third embodiment as those of the light measurement apparatus 100 of the first embodiment are denoted by the same marks as those of the first embodiment. In the following, only the respects that are different from those of the light measurement apparatus 100 of the first embodiment are described.

The light measurement apparatus 300 is composed of an optical time gate processing unit 56, a branching element 57, a time delay processing unit 58, the drive circuit 6, the polarization controllers 7 and 8, the optical phase diversity circuit 9, the AD converters 10 and 11, the data processing circuit 12 and the display unit 13.

The drive circuit 6 generates a drive signal having a period longer than the repetition period of light to be measured based on the electric clock signal input from the oscillator 1, and drives an optical modulator 56a included in the optical time gate processing unit 56 by the drive signal. Moreover, the drive circuit 6 furthermore outputs a drive signal to the AD converters 10 and 11.

The optical time gate processing unit 56 is composed of the optical modulator 56a, and performs the processing of extracting the light to be measured input from the optical signal generation apparatus 2 every n bit time (n is an integer).

The optical branching device 57 branches the light to be measured that has been processed by the optical time gate processing unit 56 into two pieces. In the following, one piece of the branched light to be measured is referred to as reference standard light.

The time delay processing unit 58 includes a variable optical delay line 58a, and gives a time delay to the one piece of the light to be measured that has been branched by the optical branching device 57. The time delay processing unit 58 adjusts the variable optical delay line 58a so that the relative time difference between the light to be measured and the reference standard light that enter the optical phase diversity circuit 9 may be an n bit time.

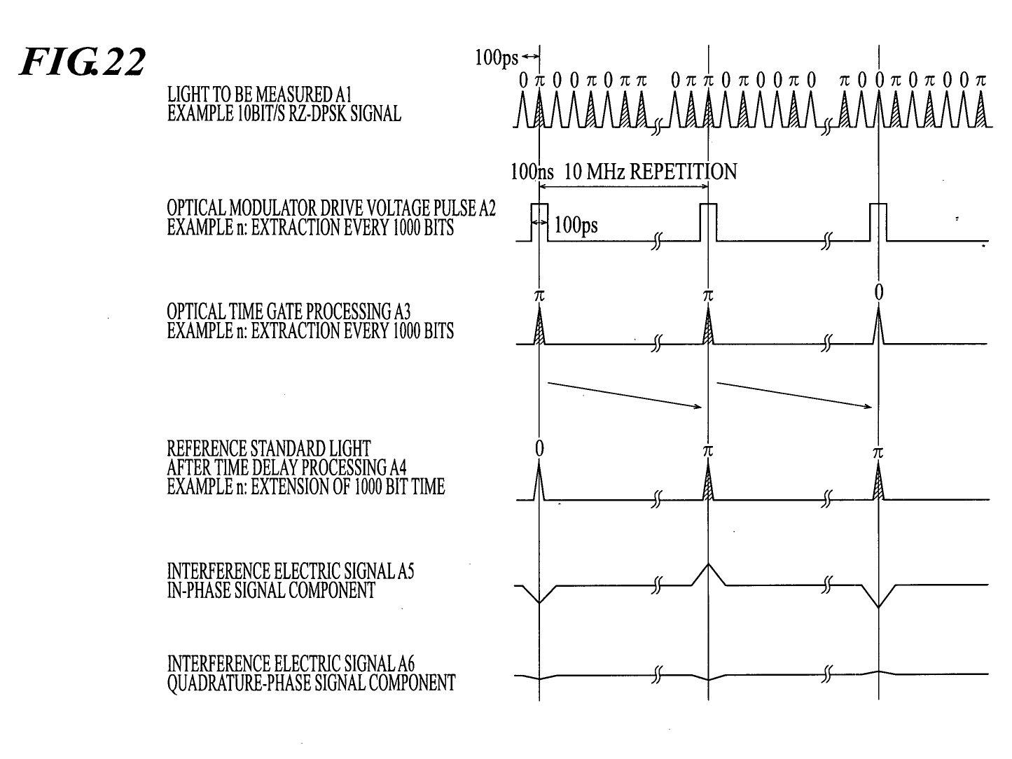

FIG. 22 shows a time chart of light to be measured A1 generated by the optical signal generation apparatus 2, a drive signal A2 output from the drive circuit 6, light to be measured A3 that has received the processing by the optical time gate processing unit 56, reference standard light A4 that has given a time delay by the time delay processing unit 58, and an in-phase signal component A5 and a quadrature-phase signal component A6 of the light to be measured output from the optical phase diversity circuit 9.

As shown in FIG. 22, when the RZ-DPSK signal of 10 Gbit/s (repetition frequency 10 GHz) is used as the light to be measured Al and the optical modulator 56a is driven by a repetition pulse train of 10 MHz (the interval of 100 ns), the light to be measured Al is extracted every 1000 bit time (n=1000). The relative time difference between the light to be measured A3 and the reference standard light A4 that will be input into the optical phase diversity circuit 9 is set to be 1000 bit time (100 ns) to the light to be measured A3 after the optical time gate processing. The optical phase diversity circuit 9 makes the input light to be measured A3 and the input reference standard light A4 interfere with each other, and then interference signals A5 and A6 can be obtained as electric signals by the light receiving elements and the differential output circuits in the optical phase diversity circuit 9.

By the operation mentioned above, the interference signals between different n bits of the light to be measured can be successively obtained at the operation period (n bit time) of the optical modulator 56a from the optical phase diversity circuit 9. After that, similarly to the first embodiment, the data of the in-phase signal output and the quadrature-phase signal output is obtained from the optical phase diversity circuit 9 in synchronization with the signal period, and the obtained data is analyzed by the data processing circuit 12. Thereby, the amplitude variation and the phase variation between different n bits of the light to be measured can be successively obtained. Moreover, an amplitude phase distribution is produced on a complex plane from the obtained measurement values, and is displayed on the display unit 13. Based on the dispersion of the plotted data of the amplitude phase distribution, the statistical distribution of the amplitude variations and the phase variations of the light to be measured can be obtained, and the quality evaluation of the optical signal becomes possible.

As described above, according to the light measurement apparatus 300 of the third embodiment, similarly to the first embodiment, it becomes possible to measure the amplitude variation and the phase variation of an optical signal without using any local light (sampling light).

In the third embodiment, it can be considered that, because only the optical signals necessary for data acquisition are input into the optical phase diversity circuit 9, the noises at the time of light reception are reduced.

In addition, the description contents of the third embodiment can be suitably changed without departing from the spirit of the present invention.

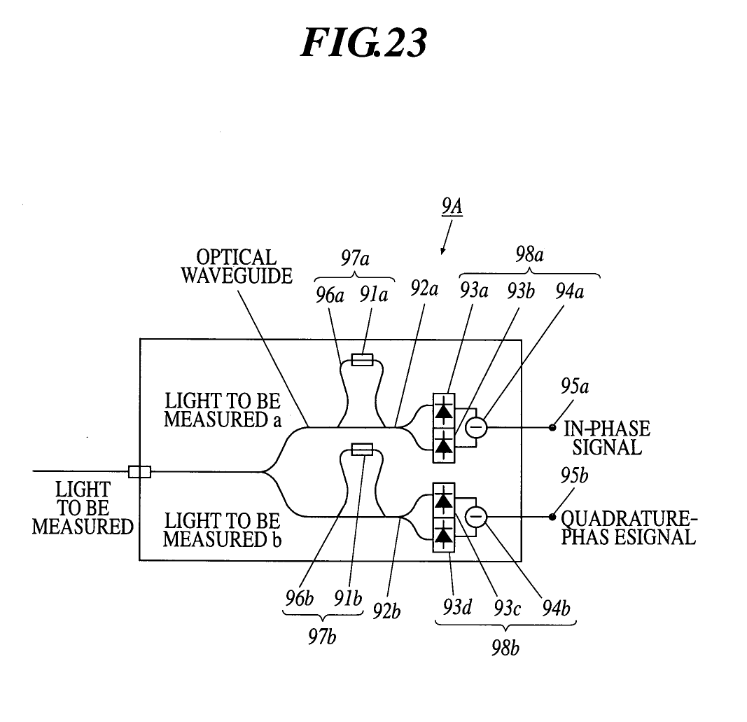

For example, in place of the time delay processing unit 58 and the optical phase diversity circuit 9, it is also possible to use an element having the functions of them as shown in FIG. 23. In addition, in the element 9A that is shown in FIG. 23 and has the functions of both of the time delay processing unit 58 and the optical phase diversity circuit 9, the same components as those of the optical phase diversity circuit 9 of FIG. 2 are denoted by the same marks as those of the optical phase diversity circuit 9. In the following, a description is given to the respects that are different from those of the optical phase diversity circuit 9 of FIG. 2.

The element 9A that is shown in FIG. 23 and has the functions of both of the time delay processing unit 58 and the optical phase diversity circuit 9 is composed of the light to be measured input port 90a, phase adjustors 91aand 91b, the directional couplers 92a and 92b, the light receiving elements 93a, 93b, 93c and 93d, the differential output circuits 94a and 94b, the in-phase signal output port 95a, the quadrature-phase signal output port 95b and delay waveguides 96a and 96b. Moreover, a delay interferometer 97a is composed of the phase adjustor 91aand the delay waveguide 96a. A delay interferometer 97b is similarly composed of the phase adjustor 91b and a delay waveguide 96b. Moreover, a differential optical receiver 98a is composed of the light receiving elements 93a and 93b, and the differential output circuit 94a. A differential optical receiver 98b is similarly composed of the light receiving elements 93c and 93d, and the differential output circuit 94b.

The light to be measured that has entered through the light to be measured input port 90a is branched into two pieces. The light to be measured a that is one piece of the branched light to be measured is further branched. One piece of the light to be measured branched from the light to be measured a is guided by the delay waveguide 96a to be input into the directional coupler 92a through the phase adjustor 91a. The light that has been guided by the delay waveguide 96a and has been input into the directional coupler 92a through the phase adjustor 91a corresponds to the reference standard light of FIG. 2. Moreover, also the other light to be measured that has been branched from the light to be measured a is input into the directional coupler 92a. The other light to be measured that has been branched from the light to be measured a corresponds to the light to be measured of FIG. 2.

The light input into the directional coupler 92a is branched into two pieces, and the branched pieces are input into the light receiving elements 93a and 93b, respectively. The light receiving elements 93a and 93b convert the input optical signals into electric signals. At this time, because the light to be measured input into the light receiving element 93a and the reference standard light interference with each other, an interference signal (including a direct-current component) according to the relative phase difference φ of both of them is output from the light receiving element 93a. Also in the light receiving element 93b, a similar interference signal can be obtained, but the interference signal the intensity of which is reverse to that of the output signal of the light receiving element 93a can be obtained owing to the characteristic of the directional coupler 92a.

The differential output circuit 94a calculates and outputs the difference between the output signals of the two light receiving elements 93a and 93b. Thereby, the direct-current components of the two interference signals are removed from them, and only the interference signal according to the phase difference φ is output from the in-phase signal output port 95a as an electric signal.

On the other hand, the other branched light to be measured b is further branched. One piece of the light to be measured that has been branched from the light to be measured b is guided to the delay waveguide 96b, and the phase difference of π/2 is added to the piece by the phase adjustor 91b. After that, the piece is input into the directional coupler 92b. The light, which has been guided by the delay waveguide 96b and has received the addition of the phase difference of π/2 by the phase adjustor 91b to be input into the directional coupler 92b after that, corresponds to the reference standard light of FIG. 2. Moreover, also the other piece of the light to be measured that has been branched from the light to be measured b is input into the directional coupler 92b. The other light to be measured that has been branched from the light to be measured b corresponds to the light to be measured of FIG. 2.

The light that has been input into the directional coupler 92b is branched into two pieces, and the pieces are input into the light receiving elements 93c and 93d, respectively. The light that has entered the light receiving elements 93c and 93d is changed into an interference signal according to the relative phase difference φ+π/2 between the input pieces of light to be obtained as an electric signal by the differential output circuit 94b, and the interference signal is output from the quadrature-phase signal output port 95b.

Because the output signal from the differential output circuit 94a and the output signal from the differential output circuit 94b become the signal components that are perpendicular to each other to the phase of the light to be measured, one of the signal components is obtained as an in-phase signal component and the other of the signal components is obtained as the quadrature-phase signal component, and are converted into digital signals. After the conversion, the data processing of the converted digital signals is performed in the data processing circuit 12.

Moreover, also in the third embodiment, it is possible to apply the internal configurations shown in FIGS. 2 and 5-7 as the optical phase diversity circuit 9. Furthermore, also in the light measurement apparatus 300 of the third embodiment, the configurations shown in the fifth to the eight modified examples of the first embodiment can be applied.

### Fourth Embodiment

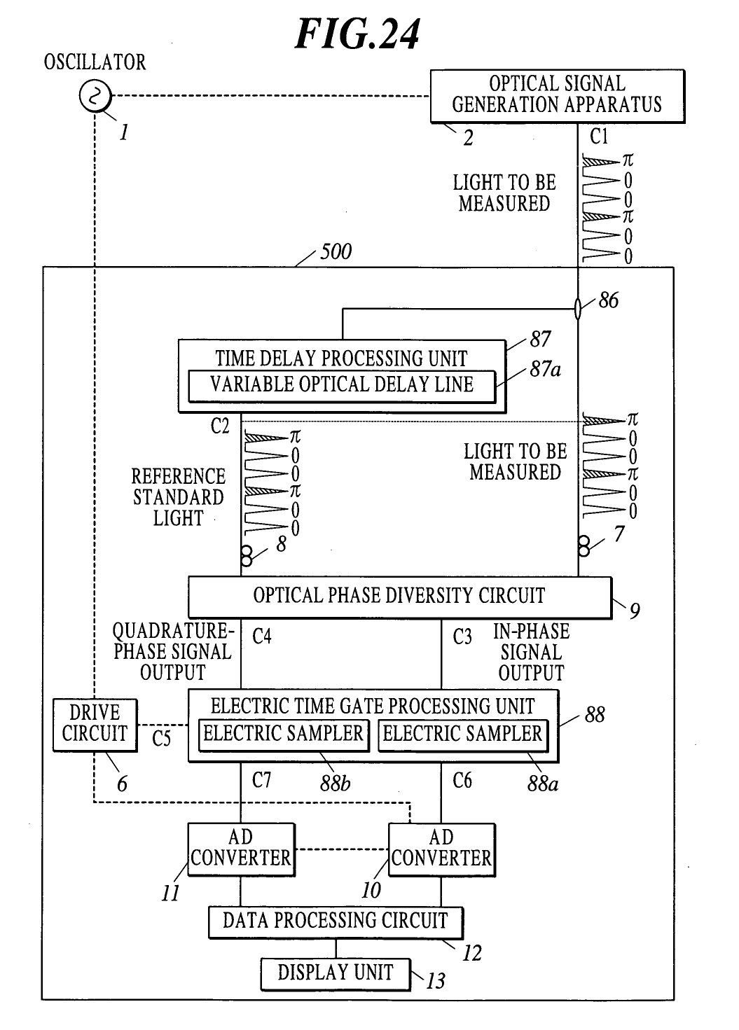

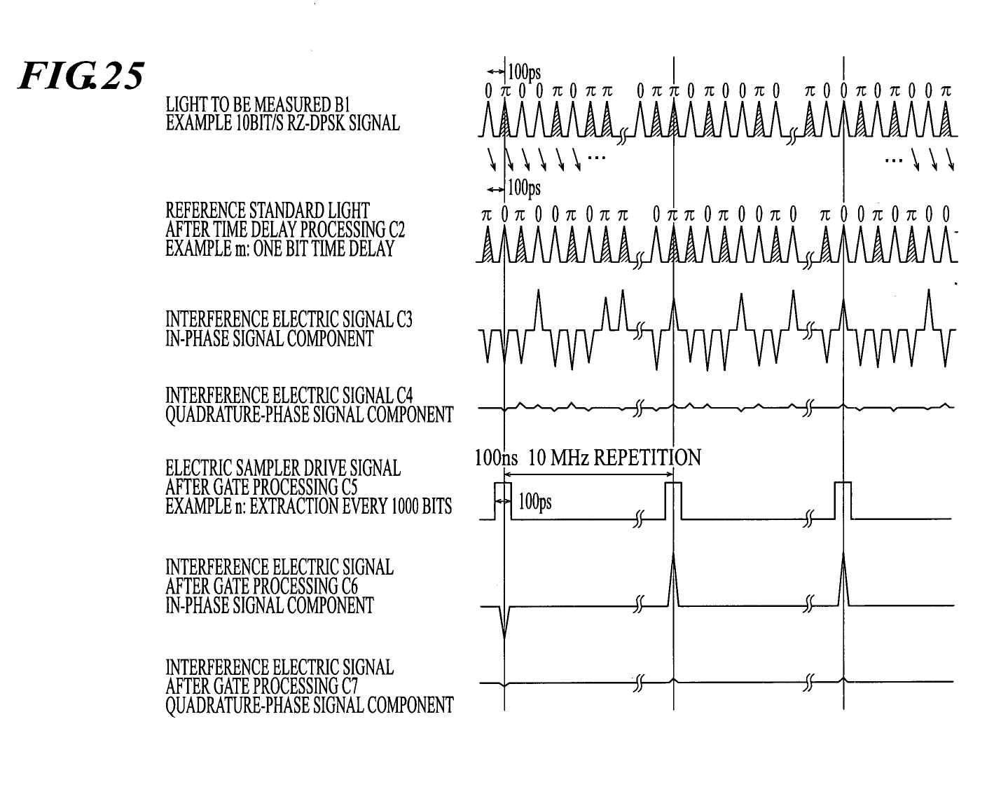

With reference to FIGS. 24 and 25, a fourth embodiment of the present invention is described.

In the fourth embodiment, an electric time gate processing unit is used.

FIG. 24 shows an example of the internal configuration of a light measurement apparatus 500 according to the fourth embodiment. In addition, in the fourth embodiment, the same constituent elements as those of the light measurement apparatus 100 of the first embodiment are denoted by the same marks as those of the light measurement apparatus 100. In the following, only the respects that are different from those of the light measurement apparatus 100 of the first embodiment are described.

The light measurement apparatus 500 is composed of an optical branching device 86, a time delay processing unit 87, the polarization controllers 7 and 8, the optical phase diversity circuit 90, an electric time gate processing unit 88, a drive circuit 89, the AD converters 10 and 11, the data processing circuit 12 and the display unit 13, as shown in FIG. 24.

The optical branching device 86 branches the light to be measured that has been input from the optical signal generation apparatus 2 into two pieces. In the following, one piece of the branched light to be measured is referred to as a reference standard light.

The time delay processing unit 87 includes a variable optical delay line 87a, and gives a time delay to the one piece of the light to be measured branched by the optical branching device 86. The time delay processing unit 87 adjusts the variable optical delay line 87a so that the relative time difference between the light to be measured and the reference standard light that are input into the optical phase diversity circuit 90 may be an m bit time (m is an integer).

The internal configuration of the optical phase diversity circuit 90 is similar to that of the optical phase diversity circuit 9 of the first embodiment shown in FIG. 2, but the light receiving elements and the differential output circuits that follow the repetition frequency of the light to be measured are used as the light receiving elements and the differential output circuits, respectively.

The electric time gate processing unit 88 is composed of electric samplers 88a and 88b, and performs the processing of extracting the in-phase signal component and the quadrature-phase signal component that have been input from the optical phase diversity circuit 90 every n bit time (n is an integer).

The drive circuit 89 generates a drive signal having a period longer than the repetition period of the light to be measured based on the electric clock signal input from the oscillator 1, and drives the electric samplers 88a and 88b included in the electric time gate processing unit 88 by the drive signal. Moreover, the drive circuit 89 furthermore outputs a drive signal to the AD converters 10 and 11.

FIG. 25 shows a time chart of light to be measured C1 generated by the optical signal generation apparatus 2, reference standard light C2 that has been given a time delay by the time delay processing unit 87, the in-phase signal component C3 of the light to be measured output from the optical phase diversity circuit 90, a quadrature-phase signal component C4, a drive signal C5 output from the drive circuit 89, and an in-phase signal component C6 and a quadrature-phase signal component C7 that have been processed by the electric time gate processing unit 88.

As shown in FIG. 25, the RZ-DPSK signal of 10 Gbit/s (repetition frequency is 10 GHz) is used as the light to be measured C1, and the relative time difference between the light to be measured C1 and the reference standard light C2 that will be input into the optical phase diversity circuit 90 is set to be one bit time (m=1), 100 ps. By the light receiving elements and the differential output circuits in the optical phase diversity circuit 90, the interference signals C3 and C4 can be obtained as electric signals. When the electric samplers 88a and 88b are driven at the same time by a repetition pulse train of 10 MHz (interval of 100 ns) to the interference signals (the in-phase signal component and the quadrature-phase signal component), the in-phase signal component C3 and the quadrature-phase signal component C4 are extracted (sampled) every 1000 bit time (n=1000).

By the operation mentioned above, the interference signals between different m bits of the light to be measured are successively obtained from the electric time gate processing unit 88 at the operation period (n bit time) of the electric samplers 88a and 88b. After that, similarly to the first embodiment, the data of the in-phase signal output and the quadrature-phase signal output is obtained in synchronization with the signal period, and the obtained data is analyzed by the data processing circuit 12. Thereby, the amplitude variation and the phase variation between different n bits of the light to be measured can be successively obtained. Moreover, an amplitude phase distribution is produced on a complex plane from the obtained measurement values, and the amplitude phase distribution is displayed on the display unit 13. From the dispersion of the plotted data of the amplitude phase distribution, a statistical distribution of the amplitude variations and the phase variations of the light to be measured can be obtained, and the quality evaluation of an optical signal becomes possible.

As mentioned above, according to the light measurement apparatus 500 of the fourth embodiment, the amplitude variation and the phase variation of an optical signal can be measured without using any local light (sampling light) similarly to the first embodiment.

Moreover, the amplitude variation and the phase variation of an optical signal can be measured without using any optical modulators.

In addition, the description contents of the fourth embodiment can be suitably changed without departing from the sprit of the present invention.

For example, similarly to the third embodiment, in place of the time delay processing unit and the optical phase diversity circuit, an element having the functions of both of them as shown in FIG. 23 can be used.

Moreover, also in the fourth embodiment, the internal configurations shown in FIGS. 2 and 5-7 can be applied as the optical phase diversity circuit 90. Furthermore, also in the light measurement apparatus 500 of the fourth embodiment, the configurations shown in the fifth to the eighth modified examples of the first embodiment can be applied.

In addition, the description contents in each of the aforesaid embodiments can be suitably changed without departing from the sprit of the present invention.

For example, a configuration of not using the optical time gate processing unit and the electric time gate processing unit in the light measurement apparatus of each of the aforesaid embodiments may be adopted.

The entire disclosure of Japanese Patent Application Nos. 2005-330045 and 2006-193070 filed on Nov. 15, 2005 and Jul. 13, 2006 respectively, including description, claims, drawings and summary are incorporated herein by reference.

What is claimed is:

1. A light measurement apparatus comprising:
an optical branching device to branch light to be. measured into a plurality of pieces;
a time delay processing unit to give a predetermined time delay to one branched piece of the light to be measured;
an optical phase diversity circuit to output an in-phase signal component and a quadrature-phase signal component of the light to be measured by interference of the light to be measured with a reference standard light whose relative time difference is a time given by the time delay, wherein the reference standard light is another branched piece of the light to be measured or the one branched piece of the light to be measured having been subjected to processing of the time delay processing unit; and
a data processing circuit to calculate at least one of an amplitude variation and a phase variation of the light to be measured based on the in-phase signal component and the quadrature-phase signal component.

2. The light measurement apparatus according to claim 1, further comprising an optical time gate processing unit to extract at least one branched piece of the light to be measured in every predetermined bit time, the optical time gate processing unit being provided on a path from the optical branching device to the optical phase diversity circuit.

3. The light measurement apparatus according to claim 1, further comprising an optical time gate processing unit to switch an optical carrier frequency of at least one branched piece of the light to be measured in every predetermined bit time, the optical time gate processing unit being provided on a path from the optical branching device to the optical phase diversity circuit.

4. The light measurement apparatus according to claim 1, further comprising an optical time gate processing unit to extract the light to be measured in every predetermined bit time, and to output the extracted light to be measured to the optical branching device.

5. The light measurement apparatus according to claim 1, further comprising an electric time gate processing unit to extract the in-phase signal component and the quadrature-phase signal component in every predetermined bit time, and to output the extracted in-phase signal component and the extracted quadrature-phase signal component to the data processing circuit.

6. The light measurement apparatus according to claim 1, further comprising an optical clock recovery circuit to generate a clock signal synchronizing with the light to be measured.

7. The light measurement apparatus according to claim 1, wherein the light to be measured is an optical signal on which a pseudo random code is superimposed, and the data processing circuit performs data processing using a frame signal synchronizing with a repetition frequency of the pseudo random code.

8. The light measurement apparatus according to claim 2, further comprising a multiplexer to multiplex the another branched piece of the light to be measured with the one branched piece of the light to be measured which has been subjected to the time delay, and to output the multiplexed light to the optical time gate processing unit, wherein
the optical time gate processing unit extracts the light to be measured multiplexed by the multiplexer in every predetermined bit time.

9. The light measurement apparatus according to claim 2, wherein the optical time gate processing unit extracts each branched piece of the light to be measured in every predetermined bit time, and
the optical phase diversity circuit makes the branched pieces of the light to be measured processed by the optical time gate processing unit interfere with each other.

10. The light measurement apparatus according to claim 3, wherein the optical time gate processing unit switches the optical carrier frequency of each branched piece of the lights to be measured in every predetermined bit time, and
the optical phase diversity circuit makes the branched pieces of the light to be measured processed by the optical time gate processing unit interfere with each other.

11. The light measurement apparatus according to claim 1, further comprising a polarization split device to split the light to be measured into a plurality of polarization components perpendicular to one another,
wherein processing of the optical branching device, the time delay processing unit and the optical phase diversity circuit is performed to each of the polarization components split by the polarization split device.

12. The light measurement apparatus according to claim 1, further comprising a measurement unit to measure intensity of at least one of the light to be measured and the reference standard light.

13. The light measurement apparatus according to claim 1, further comprising a display unit to display an amplitude phase distribution of the light to be measured based on a processing result of the data processing circuit.

14. A light measurement method comprising the steps of:
branching light to be measured into a plurality of pieces;
giving a predetermined time delay to one branched piece of the light to be measured;
outputting an in-phase signal component and a quadrature-phase signal component of the light to be measured according to interference of the light to be measured with a reference standard light whose relative time difference is a time given by the time delay, wherein the reference standard light is another branched piece of the light to be measured or the one branched piece of the light to be measured to which the time delay has been given;
calculating at least one of an amplitude variation and a phase variation of the light to be measured based on the in-phase signal component and the quadrature-phase signal component.
